(19) United States
(12) Patent Application Publication
(10) Pub. No.: US 2025/0063895 A1
(43) Pub. Date: Feb. 20, 2025

(54) DISPLAY DEVICE

(71) Applicant: Samsung Display Co., LTD., Yongin-si (KR)

(72) Inventors: Jun Hyeong PARK, Yongin-si (KR); Kyung Min KIM, Yongin-si (KR); Jun Kyul SONG, Yongin-si (KR)

(21) Appl. No.: 18/757,239

(22) Filed: Jun. 27, 2024

(30) Foreign Application Priority Data
Aug. 17, 2023 (KR) 10-2023-0107603

(51) Int. Cl. H10K 59/122

(52) U.S. Cl. CPC H10K 59/122

(57) ABSTRACT

A display device includes a substrate including an emission area and a non-emission area; a via layer on the emission area and the non-emission area of the substrate and including a first recess toward the substrate in the non-emission area; a first pixel auxiliary layer on the via layer and including a protruding tip on one side and extending in a first direction from a side surface of the first recess in the non-emission area; a first pixel electrode on the first pixel auxiliary layer; a separator on the first pixel electrode in the non-emission area; a charge generation layer on the first pixel electrode in the emission area; a charge pattern on the separator and comprising a same material as the charge generation layer; and a common electrode on the charge generation layer and the charge pattern.

### CROSS-REFERENCED TO RELATED APPLICATION

The present application claims priority to and the benefit of Korean Patent Application No. 10-2023-0107603, filed on Aug. 17, 2023, in the Korean Intellectual Property Office, the entire content of which is incorporated herein by reference.

### BACKGROUND

### 1. Field

Embodiments of the present disclosure described herein are related to a display device.

### 2. Description of the Related Art

Display devices become more and more important as multimedia technology evolves. Accordingly, a variety of display devices such as liquid-crystal display devices and/or organic light-emitting display devices are currently being developed.

Recently, virtual reality (VR) and augmented reality (AR) display devices based on head mounted displays (HMD) have been in the spotlight as next-generation display devices. For VR and AR display devices utilized relatively closer to user's eyes, it may be helpful or may be required to suppress or reduce the screen door effect (SDE) and to maintain depth perception. High-speed operation driving may also be helpful or may be essential to reduce afterimages during fast movement. In view of the above, a display device with high resolution and high brightness may be desired or may be required.

### SUMMARY

Aspects according to one or more embodiments of the present disclosure are directed toward a display device with high resolution and high brightness.

These and other aspects, embodiments and advantages of the present disclosure will become immediately apparent to those of ordinary skill in the art upon review of the Detailed Description and Claims to follow.

According to one or more embodiments of the disclosure, a display device includes a substrate including an emission area and a non-emission area; a via layer located on the emission area and the non-emission area of the substrate and including a first recess toward the substrate in the non-emission area; a first pixel auxiliary layer located on the via layer and including a protruding tip on one side of the first pixel auxiliary layer and extending in a first direction from a side surface of the first recess in the non-emission area; a first pixel electrode located on the first pixel auxiliary layer; a separator located on the first pixel electrode in the non-emission area; a charge generation layer located on the first pixel electrode in the emission area; a charge pattern located on the separator, the charge pattern and the charge generation layer include a same material; and a common electrode located on the charge generation layer and the charge pattern, wherein the charge generation layer is in contact with a side surface of the separator, and wherein the charge generation layer and the charge pattern are spaced (e.g., spaced and/or apart) from each other, and the common electrode located on the charge generation layer and the common electrode located on the charge pattern are formed as one body.

According to one or more embodiments, the separator may include a first surface located opposite to the first pixel electrode, and wherein an inclination angle formed by the side surface of the separator and the first surface may be either an acute angle or a right angle.

According to one or more embodiments, the display device may further include a first emissive layer located between the charge generation layer and the common electrode, wherein the first emissive layer covers the charge generation layer and the charge pattern, and wherein the first emissive layer may be in contact with the side surface of the separator.

According to one or more embodiments, the side of the separator may include a first portion in contact with the charge generation layer; a second portion overlapping with the charge pattern in a direction parallel to the substrate; and a third portion in contact with the first emissive layer, and wherein the third portion may be located between the first portion and the second portion.

According to one or more embodiments, the charge generation layer may include a conductive material (e.g., a conductor), and wherein the first emissive layer may not include (e.g., exclude) a conductive material (e.g., is not a conductor).

According to one or more embodiments, an undercut may be formed between the protruding tip of the first pixel auxiliary layer and the side surface of the first recess.

According to one or more embodiments, the protruding tip of the first pixel auxiliary layer may have a bottom surface facing the first recess, and a first side surface connected to the bottom surface, wherein the first pixel electrode may be in contact with the first side surface, and wherein the first pixel electrode may not be in contact with the bottom surface.

According to one or more embodiments, the display device may further include a second pixel auxiliary layer disposed in the non-emission area and spaced apart from the first pixel auxiliary layer with the separator therebetween; and a second pixel electrode located on the second pixel auxiliary layer, wherein the first pixel electrode and the second pixel electrode may be spaced from each other with the separator therebetween.

According to one or more embodiments, the display device may further include a second emissive layer located between the first pixel electrode and the charge generation layer; and an emission pattern located between the separator and the charge pattern, the emission pattern and the second emissive layer include a same material, wherein the second emissive layer and the emission pattern may be in contact with the side surface of the separator.

According to one or more embodiments, the second emissive layer and the emission pattern may be spaced from each other.

According to one or more embodiments, the display device may further include a connection electrode located between the substrate and the via layer in the emission area, wherein the via layer exposes the first via layer and the connection electrode and includes a second via layer spaced from the first via layer in a direction parallel to the substrate.

According to one or more embodiments, the first via layer and the second via layer may be spaced from each other by a pixel electrode contact hole in the emission area, and wherein the pixel electrode contact hole may be located inside the separator in a plan view (e.g., when viewed from the top or in a top view).

According to one or more embodiments, the first pixel auxiliary layer may further include a first subsidiary portion in contact with the first via layer; and a second subsidiary portion spaced (e.g., spaced and/or apart) from the first subsidiary portion by the pixel electrode contact hole and in contact with the second via layer, and wherein the first subsidiary portion and the second subsidiary portion may be connected by the first pixel electrode.

According to one or more embodiments, the separator may have a reverse taper shape.

According to one or more embodiments, the first recess may be filled with a same material as the separator, and wherein the first recess and the separator are formed or provided as one body (e.g., one integral or monolithic body).

According to one or more embodiments, the first surface of the separator may include a second recess toward the substrate.

According to one or more embodiments of the disclosure, a display device may include a substrate including a display area and a non-display area, the display area including an emission area and a non-emission area; a via layer located on the substrate and including a recess toward the substrate in the non-emission area; a first pixel auxiliary layer located on the via layer and including a protruding tip on one side of the first pixel auxiliary layer and extending in a first direction from a side surface of the recess in the non-emission area; a first pixel electrode located on the first pixel auxiliary layer; a first pixel electrode pattern located in the recess, the first pixel electrode pattern and the first pixel electrode include a same material and is spaced from the first pixel electrode; a separator located on the first pixel electrode in the non-emission area; and a power electrode located in the non-display area and surrounding the display area, wherein the separator does not overlap with the emission area, and wherein the separator completely surrounds the emission area in a plan view.

According to one or more embodiments, the first pixel electrode pattern may not overlap with the emission area, and wherein the separator and the first pixel electrode pattern have a mesh pattern in the plan view.

According to one or more embodiments, the first pixel electrode pattern may be connected to the power electrode in the non-display area in the plan view.

According to one or more embodiments, the separator and the first pixel electrode pattern may overlap each other in the plan view.

According to embodiments of the present disclosure, a separator that defines emission areas of pixels is formed in a reverse taper structure in a display device, so that the aperture ratio of the display area can be increased. Therefore, according to the embodiments, a display device with high resolution, high brightness and high efficiency can be provided.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in more detail embodiments thereof with reference to the attached drawings, in which:

FIG. 1 is a perspective view showing an electronic device according to an embodiment of the present disclosure.

FIG. 2 is a perspective view showing a display device included in an electronic device according to an embodiment of the present disclosure.

FIG. 3 is a cross-sectional view showing a structure of the display device according to an embodiment.

FIG. 4 is a plan view schematically showing the display layer of FIG. 3.

FIG. 5 is a plan view showing a layout of emission areas in the display area of FIG. 3.

FIG. 6 is a cross-sectional view taken along line X1-X1′ of FIG. 5.

FIGS. 7 and 8 are cross-sectional views showing the emission material layer of FIG. 6.

FIG. 9 is an enlarged cross-sectional view showing the periphery of the first light-emitting element in the first emission area of FIG. 6.

FIG. 10 is an enlarged cross-sectional view of area A of FIG. 6.

FIG. 11 is an enlarged cross-sectional view of area C1 of FIG. 10.

FIG. 12 is an enlarged, cross-sectional view of area C3 of FIG. 11.

FIG. 13 is a plan view showing the separator and the pixel electrode pattern in the display area.

FIG. 14 is a plan view showing a layout of separators in a display area according to another embodiment.

FIG. 15 is an enlarged plan view of area V of FIG. 4.

FIG. 16 is an enlarged cross-sectional view of another example of area A of FIG. 6.

FIG. 17 is an enlarged cross-sectional view of area E of FIG. 16 according to another embodiment.

### DETAILED DESCRIPTION

The present disclosure will now be described more fully herein with reference to the accompanying drawings, in which some embodiments of the present disclosure are shown. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

It is also to be understood that when a layer is referred to as being “on” another layer or substrate, it may be directly on the other layer or substrate, or one or more intervening layers may also be present. The same reference numbers indicate the same components throughout the specification.

It is to be understood that, although the terms “first,” “second,” etc. may be utilized herein to describe one or more suitable elements, these elements should not be limited by these terms. These terms are utilized to distinguish one element from another element. For instance, a first element discussed herein could be termed a second element without departing from the teachings of the present disclosure. Similarly, the second element could also be termed a first element.

Unless otherwise defined, all terms (including technical and scientific terms) utilized herein have the same meaning as commonly understood by one of ordinary skill in the art to which the present disclosure pertains. It is also to be understood that terms defined in commonly utilized dictionaries should be interpreted as having meanings consistent with the meanings in the context of the related art, and are expressly defined herein unless they are interpreted in an ideal or overly formal sense.

Hereinafter, embodiments of the present disclosure will be described in more detail with reference to the accompanying drawings.

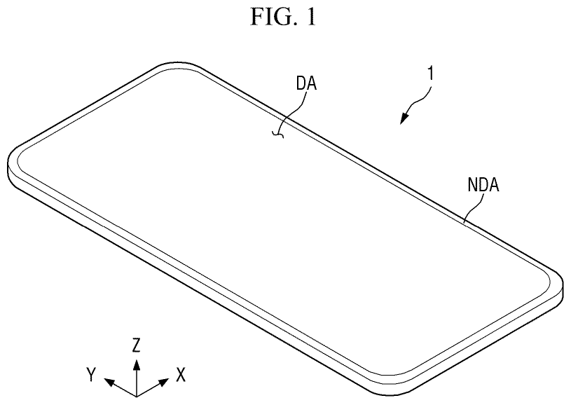

FIG. 1 is a perspective view of an electronic device according to an embodiment of the present disclosure.

Referring to FIG. 1, an electronic device 1 displays a moving image or a still image. The electronic device 1 may refer to any electronic device that provides a display screen. For example, the electronic device 1 may include a television set, a laptop computer, a monitor, an electronic billboard, an Internet of Things device, a mobile phone, a smart phone, a tablet personal computer (PC), an electronic watch, a smart watch, a watch phone, a head-mounted display device, a mobile communications terminal, an electronic notebook, an electronic book, a portable multimedia player (PMP), a navigation device, a game console and a digital camera, a camcorder, etc.

In FIG. 1, a first direction (x-axis direction), a second direction (y-axis direction) and a third direction (z-axis direction) are defined. The first direction (x-axis direction) and the second direction (y-axis direction) may be perpendicular (e.g., substantially perpendicular or normal) to each other, the first direction (x-axis direction) and the third direction (z-axis direction) may be perpendicular (e.g., substantially perpendicular or normal) to each other, and the second direction (y-axis direction) and the third direction (z-axis direction) may be perpendicular (e.g., substantially perpendicular or normal) to each other. The first direction (x-axis direction) may refer to the horizontal direction in the drawings, the second direction (y-axis direction) may refer to the vertical direction in the drawings, and the third direction (z-axis direction) may refer to the up-and-down direction, i.e., the thickness direction in the drawings. As utilized herein, a direction may refer to the direction indicated by the arrow as well as the opposite direction, unless specifically stated otherwise. When it is necessary to discern between such two opposite directions, one of the two directions may be referred to as “one side in the direction,” while the other direction may be referred to as “the opposite side in the direction.” In FIG. 1, the side indicated by an arrow indicative of a direction is referred to as one side in the direction, while the opposite side is referred to as the opposite side in the direction.

In the following description of the surfaces of the electronic device 1 or the elements of the electronic device 1, the surface facing one side where images are displayed, i.e., the side indicated by the arrow in the third direction (z-axis direction) will be referred to as the upper surface, while the opposite surface will be referred to as the lower surface, for convenience of illustration. It should be understood, however, that the present disclosure is not limited thereto. The surfaces and the opposite surface of each of the elements may be referred to as a front surface and a rear surface, respectively, or may be referred to as a first surface and a second surface, respectively. In some embodiments, in the description of relative positions of the elements of the electronic device 1, one side in the third direction (z-axis direction) may be referred to as the upper side while the opposite side in the third direction (z-axis direction) may be referred to as the lower side.

The shape of the electronic device 1 may be modified in a variety of ways. For example, the electronic device 1 may have shapes such as a rectangle with longer lateral sides, a rectangle with longer vertical sides, a square, a quadrangle with rounded corners (vertices), other polygons, a circle, etc.

The electronic device 1 may include the display area DA and a non-display area NDA. In the display area DPA, images can be displayed. In the non-display area NDA, images are not displayed. The display area DPA may be referred to as an active area, while the non-display area NDA may also be referred to as an inactive area. The display area DA may generally occupy the center of the electronic device 1.

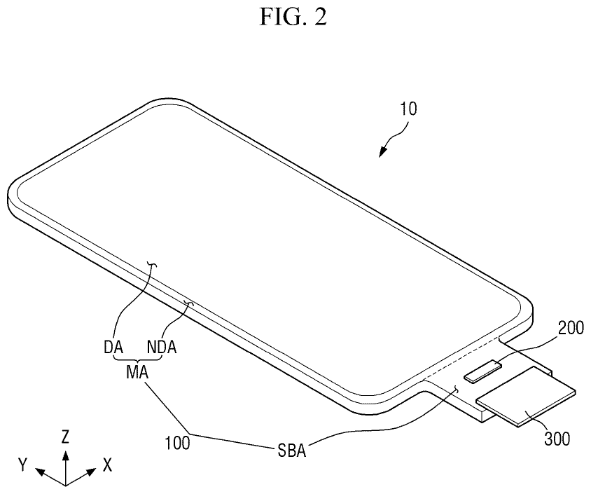

FIG. 2 is a perspective view showing a display device 10 included in the electronic device 1 according to the embodiment.

Referring to FIG. 2, the electronic device 1 according to the embodiment may include the display device 10. The display device 10 may provide a display screen where images are displayed in the electronic device 1. Examples of the display device 10 may include an inorganic light-emitting diode display device, an organic light-emitting display device, a quantum-dot light-emitting display device, a plasma display device, a field emission display device, etc. In the following description, an organic light-emitting diode display device is employed as an example of the display device, but the present disclosure is not limited thereto. Any other display device may be employed as long as the technical idea of the present disclosure can be equally applied.

The display device 10 may have a shape similar to that of the electronic device 1 in a plan view (e.g., when viewed from the top or in a top view). For example, the display device 10 may have a shape similar to a rectangle having shorter sides in the first direction (x-axis direction) and longer sides in the second direction (y-axis direction). The corners where the shorter sides in the first direction (x-axis direction) meet the longer sides in the second direction (y-axis direction) may be rounded with a set or predetermined curvature. It should be understood, however, that the present disclosure is not limited thereto. The corners may be formed at a right angle. The shape of the display device 10 in a plan view is not limited to a quadrangular shape, but may be formed in a shape similar to other polygonal shapes, a circular shape, or an elliptical shape.

The display device 10 may include a display panel 100, a display driver 200 and a circuit board 300.

The display panel 100 may include a main area MA and a subsidiary area SBA. The main area MA may include the display area DA including pixels for displaying images, and the non-display area NDA located around the display area DA.

The display area DA may be configured to emit light from a plurality of emission areas or a plurality of opening areas to be described later. For example, the display panel 100 may include a pixel circuit including switching elements, a pixel-defining layer that defines the emission areas or the opening areas, and a self-light-emitting element. For example, the self-light-emitting element may include, but is not limited to, at least one of: an organic light-emitting diode including an organic emissive layer, a quantum-dot light-emitting diode (quantum LED) including a quantum-dot emissive layer, an inorganic light-emitting diode (inorganic LED) including an inorganic semiconductor, or a micro light-emitting diode (micro LED). In the following drawings, it is illustrated that the self-luminous element is an organic light-emitting diode.

The non-display area NDA may be disposed on the outer side of the display area DA. The non-display area NDA may be defined as the edge of the main area MA of the display panel 100. The non-display area NDA may include a line drive that supplies signals to the display area DA, and lines connecting the display driver 200 with the display area DA.

The subsidiary area SBA may be extended from one side of the main area MA. The subsidiary area SUB may include a flexible material that can be bent, folded, or rolled. For example, when the subsidiary area SBA is bent, the subsidiary area SBA may overlap the main area MA in the thickness direction (e.g., the third direction or z-axis direction). The subsidiary area SBA may include pads connected to the display driver 200 and the circuit board 300. According to another embodiment, the subsidiary area SBA may be eliminated, and the display driver 200 and the pads may be disposed in the non-display area NDA.

The display driver 200 may output signals and voltages for driving the display panel 100. The display driver 200 may supply data voltages to data lines. The display driver 200 may apply a supply voltage to a voltage line and may supply gate control signals to the gate driver. The display driver 200 may be implemented as an integrated circuit (IC) and may be attached on the display panel 100 by a chip-on-glass (COG) technique, a chip-on-plastic (COP) technique, or ultrasonic bonding. For example, the display driver 200 may be disposed in the subsidiary area SBA and may overlap with the main area MA in the thickness direction as the subsidiary area SBA is bent. For another example, the display driver 200 may be mounted on the circuit board 300.

The circuit board 300 may be attached on the pad area of the display panel 100 utilizing an anisotropic conductive film (ACF). Lead lines of the circuit board 300 may be electrically connected to the pads of the display panel 300. The circuit board 300 may be a flexible printed circuit board (FPCB), a printed circuit board (PCB), or a flexible film such as a chip-on-film (COF).

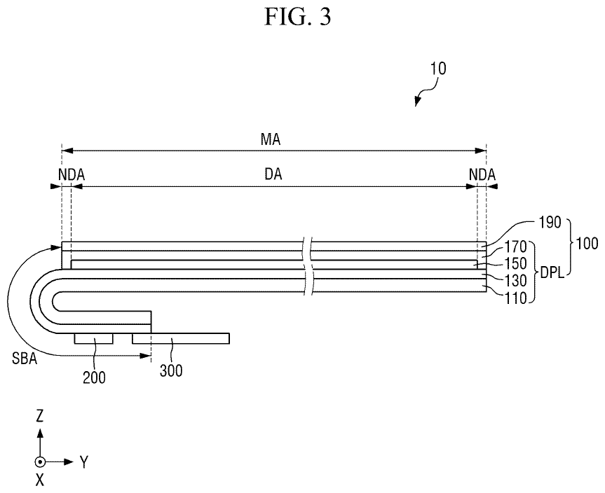

FIG. 3 is a cross-sectional view showing a structure of the display device 10 according to the embodiment.

Referring to FIG. 3, the display panel 100 may include a display layer DPL and a color filter layer 190. The display layer DPL may include a substrate 110, a thin-film transistor layer 130, a display element layer 150, and a thin-film encapsulation layer 170.

The substrate 110 may be a base substrate or a base member. The substrate 110 may be a flexible substrate that can be bent, folded, or rolled. For example, the substrate 110 may include, but is not limited to, a polymer resin such as polyimide PI. According to another embodiment, the substrate 110 may include a glass material or a metal material.

The thin-film transistor layer 130 may be disposed on the substrate 110. The thin-film transistor layer 130 may be disposed in the display area DA, the non-display area NDA and the subsidiary area SBA. The thin-film transistors included in the thin-film transistor layer TFTL, the gate lines, the data lines and the voltage lines may be disposed in the display area DA. A plurality of thin-film transistors may form pixel circuits of the pixels connected thereto. The gate control lines and the fan-out lines in the thin-film transistor layer 130 may be disposed in the non-display area NDA. The lead lines of the thin-film transistor layer 130 may be disposed in the subsidiary area SBA.

The display element layer 150 may be disposed on the thin-film transistor layer 130. The display element layer 150 may include a plurality of light-emitting elements including pixel electrodes, an emission material layer and a common electrode to emit light, and a separator that define the pixels. The plurality of light-emitting elements in the display element layer 150 may be disposed in the display area DA.

According to an embodiment of the present disclosure, the light-emitting elements may be organic light-emitting elements containing an organic material. A light-emitting element may include a hole transporting layer, an organic light-emitting layer and an electron transporting layer. When the pixel electrode receives a voltage through the thin-film transistors of the thin-film transistor layer 130 and the common electrode receives a cathode voltage, the holes and electrons may move to the organic light-emitting layer through the hole transporting layer and the electron transporting layer, respectively, such that they combine in the organic light-emitting layer to emit light.

According to another embodiment, the light-emitting elements may include quantum-dot light-emitting diodes each including a quantum-dot emissive layer, inorganic light-emitting diodes each including an inorganic semiconductor, or micro light-emitting diodes.

The thin-film encapsulation layer 170 may cover the upper and side surfaces of the display element layer 150, and can protect the display element layer 150. The thin-film encapsulation layer 170 may include at least one inorganic film and at least one organic film for encapsulating the display element layer 150.

The color filter layer 190 may be disposed on the thin-film encapsulation layer 170. The color filter layer 190 may include a plurality of color filters associated with the plurality of emission areas, respectively. Each of the color filters may selectively transmit light of a particular wavelength and block or reduce or absorb lights of other wavelengths. The color filter layer 190 may be configured to absorb some of lights introduced from the outside of the display device 10 to reduce the reflection of external light. Accordingly, the color filter layer 190 can prevent or reduce distortion of colors due to the reflection of external light.

Because the color filter layer 190 is disposed directly on the thin-film encapsulation layer 170, the display device 10 may require no separate substrate for the color filter layer 190. Therefore, the thickness of the display device 10 can be relatively small.

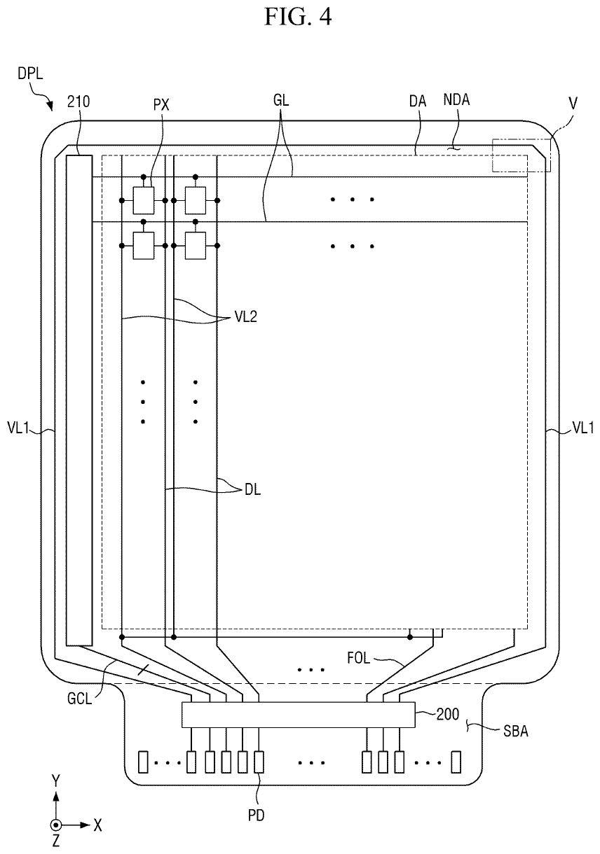

FIG. 4 is a schematic plan view of the display layer DPL in FIG. 3.

Referring to FIG. 4, in the display area DA of the display layer DPL, a plurality of pixels PX, a plurality of gate lines GL, a plurality of data lines DL and second voltage lines VL2 may be located. Each of the plurality of pixels PX may be defined as the minimum unit that outputs light.

The plurality of gate lines GL may supply the gate signals received from the gate driver 210 to the plurality of pixels PX. The plurality of gate lines GL may be extended in the first direction (x-axis direction) and may be spaced (e.g., spaced and/or apart) from each other in the second direction (y-axis direction) crossing the first direction (x-axis direction).

The plurality of data lines DL may supply the data voltages received from the display driver 200 to the plurality of pixels PX. The plurality of data lines DL may be extended in the second direction (y-axis direction) and may be spaced from each other in the first direction (x-axis direction).

The second voltage lines VL2 may apply the supply voltage received from the display driver 200 to the plurality of pixels PX. The supply voltage may be at least one of a driving voltage, an initialization voltage, or a reference voltage. The plurality of second voltage lines VL2 may be extended in the second direction (y-axis direction) and may be spaced from each other in the first direction (x-axis direction).

The non-display area NDA of the display layer DPL may surround the display area DA. In the non-display area NDA, first voltage lines VL1, the gate driver 210, fan-out lines FOL, and gate control lines GCL may be disposed. The gate driver 210 may generate a plurality of gate signals based on the gate control signal, and may sequentially supply the plurality of gate signals to the plurality of gate lines GL in a set or predetermined order.

The first voltage line VL1 may surround the display area DA and may be disposed in the non-display area NDA. The first voltage line VL1 may apply the supply voltage received from the display driver 200 to the plurality of pixels PX. The supply voltage may be a low-level supply voltage.

The fan-out lines FOL may be extended from the display driver 200 to the display area DA. The fan-out lines FOL may supply the data voltage received from the display driver 200 to the plurality of data lines DL.

The gate control lines GCL may be extended from the display driver 200 to the gate driver 210. The gate control lines GCL may supply the gate control signal received from the display driver 200 to the gate driver 210. Although the gate driver 210 is disposed only in the non-display area NDA on the left side of the display area DA in the drawings, the present disclosure is not limited thereto. According to some embodiments, the display device 10 may include a plurality of gate drivers 210 disposed on the left and right sides of the display area DA, respectively.

The subsidiary area SBA of the display layer DPL may include the display driver 200 and a plurality of display pads PD.

The display driver 200 may output signals and voltages for driving the display panel 100 to the fan-out lines FOL. The display driver 200 may supply data voltages to the data lines DL through the fan-out lines FOL. The data voltages may be applied to the plurality of pixels PX, so that the luminance of the plurality of pixels PX may be controlled or selected. The display driver 200 may supply a gate control signal to the gate driver 210 through the gate control lines GCL.

The plurality of display pads DP may be connected to a graphic system through the circuit board 300. The plurality of display pads DP may be connected to the circuit board 300 to receive digital video data and may supply the digital video data to the display driver 200.

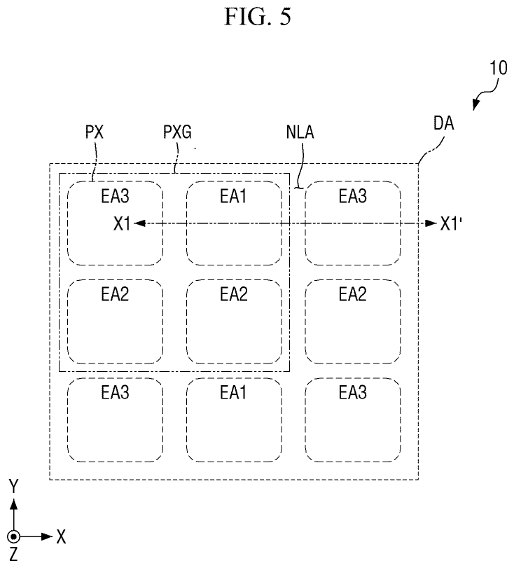

FIG. 5 is a plan view showing a layout of emission areas in the display area DA of FIG. 3.

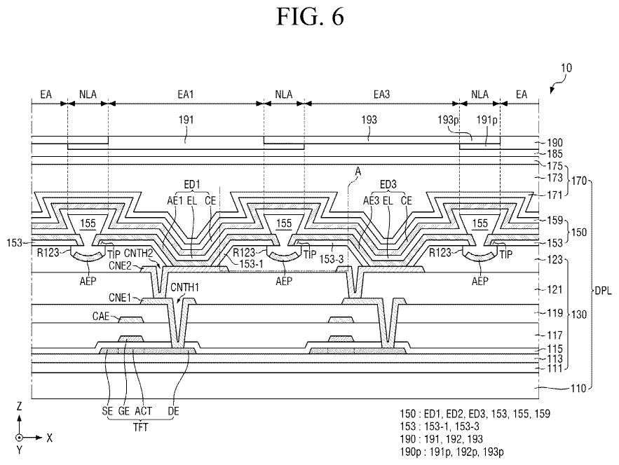

Referring to FIG. 5, the display device 10 may include a plurality of emission areas EA1, EA2 and EA3 and a non-emission area NLA arranged in the display area DA. A plurality of emission areas EA1, EA2 and EA3 and the non-emission area NLA may be defined by a separator 155 (see FIG. 6), which will be described later.

The plurality of pixels PX may include emission areas EA1, EA2 and EA3 that are configured to emit lights of different colors. For example, the display device 10 may include a first emission area EA1 that is configured to emit a light of a first color (for example, red light with a wavelength range of approximately (e.g., about) 610 nm to approximately 680 nm and a peak wavelength in the 610 nm to 650 nm range (e.g., approximately 620 nm to approximately 623 nm)); a second emission area EA2 that is configured to emit a light of a second color (for example, green light with a wavelength range of approximately 500 nm to approximately 570 nm and a peak wavelength in the 510 nm to 550 nm range (e.g., approximately 520 nm to approximately 530 nm)); and a third emission area EA3 that is configured to emit a light of a third color (for example, blue light with a wavelength range of approximately 430 nm to approximately 500 nm and a peak wavelength in the 440 nm to 480 nm range (e.g., approximately 450 nm to approximately 460 nm). The basic colors of lights emitted from each of the emission areas EA1, EA2 and EA3 may vary depending on the embodiments.

As shown in FIG. 5, a plurality of emission areas EA1, EA2 and EA3 may be arranged in a variety of layouts in the display area DA. For example, first emission areas EA1 and third emission areas EA3 may be spaced from each other in the first direction (x-axis direction), and second emission areas EA2 may be spaced from the first emission areas EA1 and the third emission areas EA3 in the second direction (y-axis direction). A plurality of neighboring second emission areas EA2 may be spaced in the first direction (x-axis direction). It should be understood, however, that the present disclosure is not limited thereto. The arrangement structure of the emission areas EA1, EA2 and EA3 may be changed in one or more suitable ways.

A plurality of pixels PX including at least one first emission area EA1, at least two second emission areas EA2 and at least one third emission area EA3 arranged adjacent to each other and may form a single pixel group PXG. A pixel group PXG may be the minimum unit that is configured to emit white light. However, the type or kind and/or number of emission areas EA1, EA2 and EA3 forming each pixel group PXG may vary depending on embodiments.

The display device 10 may include light-emitting elements ED (see FIG. 6) disposed in the emission areas EA1, EA2 and EA3. The light-emitting elements ED1, ED2 and ED3 may include pixel electrodes separately disposed in the respective emission areas EA1, EA2 and EA3, a common electrode facing the pixel electrodes and commonly disposed across a plurality of emission areas EA1, EA2 and EA3, and emission stacks including interposed between the pixel electrodes and the common electrode and including at least one emissive layer.

The emission stacks according to this embodiment may generate lights of the same color in a plurality of emission areas EA1, EA2 and EA3. As an example, the emission stacks according to this embodiment may generate white light, but the present disclosure is not limited thereto.

In the display device 10, color filters 190 (see FIG. 6) associated with the colors of lights output from the emission areas EA1, EA2 and EA3 may be disposed in line with a plurality of emission areas EA1, EA2 and EA3, respectively. This will be described in more detail later.

The non-emission area NLA may be located such that it surrounds the emission areas EA1, EA2 and EA3. The non-emission area NLA can prevent or reduce the lights exiting from the emission areas EA1, EA2 and EA3 from being mixed. The separators may overlap with the non-emission area NLA.

FIG. 6 is a cross-sectional view taken along line X1-X1′ of FIG. 5.

As described above, the display device 10 may include the display layer DPL and the color filter layer 190, and the display layer DPL may include the substrate 110, the thin-film transistor layer 130, the display element layer 150 and the thin-film encapsulation layer 170. The substrate 110 has been described above and thus will not be described again.

Referring to FIG. 6, the thin-film transistor layer 130 may include a first buffer layer 111, a second buffer layer 113, a thin-film transistor TFT, a gate insulator 115, a first interlayer dielectric layer 117, a second interlayer dielectric layer 119, a first connection electrode CNE1, a first via layer 121, a second connection electrode CNE2 and a second via layer 123.

The first buffer layer 111 may be disposed on the first substrate 110. The first buffer layer 111 may include an inorganic film capable of preventing or reducing permeation of air or moisture. For example, the first buffer layer 111 may include a plurality of inorganic films stacked on one another alternately. For example, the first buffer layer 111 may be made up of multiple layers in which one or more inorganic layers of a silicon nitride layer, a silicon oxynitride layer, a silicon oxide layer, a titanium oxide layer and an aluminum oxide layer are alternately stacked on one another.

The second buffer layer 113 may cover the first buffer layer 111. The second buffer layer 113 may include an inorganic film capable of preventing or reducing permeation of air or moisture. For example, the second buffer layer 113 may include a plurality of inorganic films stacked on one another alternately. The second buffer layer 113 may include the same material as the first buffer layer 111.

In some embodiments, a bottom metal layer BML may be included between the first buffer layer 111 and the second buffer layer 113.

The thin-film transistor TFT may be disposed on the second buffer layer 113. The thin-film transistor TFT may include an active layer ACT, a gate electrode GE, a source electrode SE, and a drain electrode DE. The active layer ACT of the thin-film transistor TFT includes polycrystalline silicon, single crystal silicon, low-temperature polycrystalline silicon, amorphous silicon, or an oxide semiconductor. The active layer ACT may overlap with the gate electrode GE in the third direction (z-axis direction), which is the thickness direction of the substrate 110, and the source electrode SE and the drain electrode DE may not overlap with the gate electrode GE in the third direction (z-axis direction). The active layer ACT may be defined as a channel region. The source electrode SE and the drain electrode DE may have conductivity by doping ions or impurities into a silicon semiconductor or an oxide semiconductor.

The gate insulator 115 may be disposed on the thin-film transistor TFT. The gate insulator 115 may cover the thin-film transistor TFT and the second buffer layer 113, and may insulate the active layer ACT from the gate electrode GE. The gate insulator 115 may be disposed to have substantially the same thickness along the profile of the thin film transistor TFT. The gate insulator 115 may include a first contact hole CNTH1 through which the first connection electrode CNE1 passes. The gate insulator 115 may include an inorganic insulating material and may be made up of multiple layers. For example, the gate insulator 115 may be made of an inorganic material such as a silicon nitride layer, a silicon oxynitride layer, a silicon oxide layer, a titanium oxide layer, and an aluminum oxide layer.

The gate electrode GE may be disposed on the gate insulator 115. The gate electrode GE may overlap the active layer ACT with the gate insulator 115 interposed therebetween. The gate electrode GE may include a metal. For example, the gate electrode GE may include at least one metal selected from among the group consisting of: molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu).

The first interlayer dielectric layer 117 may be disposed on the gate electrode GE. The first interlayer dielectric layer 117 may include an inorganic insulating material and may be made up of multiple layers. For example, the first interlayer dielectric layer 117 may be formed as a silicon nitride layer, a silicon oxynitride layer, a silicon oxide layer, a titanium oxide layer, or an aluminum oxide layer. The first interlayer dielectric layer 117 may include a first contact hole CNTH1 through which the first connection electrode CNE1 passes.

A capacitor electrode CAE may be disposed on the first interlayer dielectric layer 117. The capacitor electrode CAE may overlap with the gate electrode GE of the thin-film transistor TFT in the third direction (z-axis direction). Because the first interlayer dielectric layer 117 has a set or predetermined dielectric constant, a capacitor can be formed by the capacitor electrode CAE, the gate electrode GE, and the first interlayer dielectric layer 117 disposed between them. The capacitor electrode CAE may include a metal. For example, the capacitor electrode CAE may include at least one metal selected from among the group consisting of: molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu).

The second interlayer dielectric layer 119 may be located on the first interlayer dielectric layer 117 and the capacitor electrode CAE. The second interlayer dielectric layer 119 may include an inorganic insulating material and may be made up of multiple layers. For example, the second interlayer dielectric layer 119 may be formed as a silicon nitride layer, a silicon oxy nitride layer, a silicon oxide layer, a titanium oxide layer, or an aluminum oxide layer. The second interlayer dielectric layer 119 may include the first contact hole CNTH1 through which the first connection electrode CNE1 passes.

The first connection electrode CNE1 may be disposed on the second interlayer dielectric layer 119. The first connection electrode CNE1 may electrically connect the drain electrode DE of the thin-film transistor TFT with the second connection electrode CNE2. The first connection electrode CNE1 may be inserted into the first contact hole CNTH1 formed in the first interlayer dielectric layer 117, the second interlayer dielectric layer 119 and the gate insulator 115 to be in contact with the drain electrode DE of the thin-film transistor TFT.

The first via layer 121 may cover the first connection electrode CNE1 and the second interlayer dielectric layer 119. The first via layer 121 may provide a flat surface over the underlying structures. The first via layer 121 may include an organic material. As an example, the first via layer 121 may include an organic material such as an acrylic resin, an epoxy resin, a phenol resin, a polyamide resin and a polyimide resin. The first via layer 121 may include a second contact hole CNTH2 through which the second connection electrode CNE2 passes.

The second connection electrode CNE2 may be disposed on the first via layer 121. The second connection electrode CNE2 may electrically connect the first connection electrode CNE1 with the pixel electrodes AE1, AE2 and AR3 of the light-emitting elements ED1, ED2 and ED3. The second connection electrode CNE2 may be brought into contact with the first connection electrode CNE1 through the second contact hole CNTH2 formed in the first via layer 121.

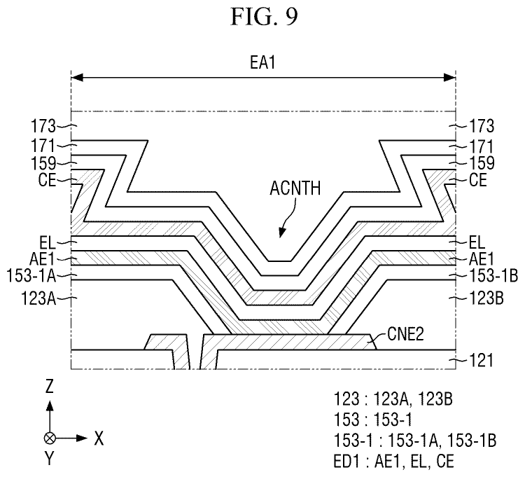

The second via layer 123 may be disposed on the second connection electrode CNE2 and the first via layer 121. The second via layer 123 may expose a part of the second connection electrode CNE2 by a pixel electrode contact hole ACNTH (see FIG. 9) and may be spaced from one another. In other words, the second via layer 123 may overlap with the emission areas EA1, EA2 and EA3 and may expose the second connection electrode CNE2 by the pixel electrode contact hole ACNTH (see FIG. 9). This will be described in more detail later.

The second via layer 123 may include a recess R123 in line with the non-emission area NLA that is recessed toward the first via layer 121. The inside of the recess R123 may be filled with the same material as the separators 155. This will be described in more detail later.

The second via layer 123 may include an organic material. As an example, the second via layer 123 may include an organic material such as an acrylic resin, an epoxy resin, a phenol resin, a polyamide resin and a polyimide resin. The second contact hole CNTH2 may be filled with the second via layer 123.

The display element layer 150 may be located on the second via layer 123. The display element layer 150 according to this embodiment may include a pixel auxiliary layer 153, light-emitting elements ED1, ED2 and ED3, a separator, and a capping layer 159.

The pixel auxiliary layer 153 may be located on the second via layer 123 and the second connection electrode CNE2. The pixel auxiliary layer 153 may expose a part of the second connection electrode CNE2 and may cover the second via layer 123 along it. The pixel auxiliary layer 153 may cover the second via layer 123 along the profile with a constant thickness. Accordingly, the pixel auxiliary layer 153 may include steps.

The pixel auxiliary layer 153 may include an inorganic film. For example, the pixel auxiliary layer 153 may be one of silicon nitride, silicon oxide, and silicon oxynitride.

According to some embodiments, the pixel auxiliary layer 153 may include first to third pixel auxiliary layers 153-1, 153-2 and 153-3 in line with the emission areas EA1, EA2 and EA3. For example, the pixel auxiliary layer 153 may include a first pixel auxiliary layer 153-1 in the first emission area EA1, a second pixel auxiliary layer 153-2 in the second emission area EA2, and a third pixel auxiliary layer 153-3 in the third emission area EA3.

The first to third pixel auxiliary layers 153-1, 153-2 and 153-3 overlapping the respective emission areas EA1, EA2 and EA3 may be spaced from one another in the non-emission area NLA. In other words, the first to third pixel auxiliary layers 153-1, 153-2 and 153-3 overlapping with the respective emission areas EA1, EA2 and EA3 may be spaced from one another in the recess R123 of the second via layer 123. The first to third pixel auxiliary layers 153-1, 153-2 and 153-3 spaced from one another may include tips TIP that protrude toward the non-emission area NLA than the inside of the recess R123 of the second via layer 123. The protruding tips TIP of the pixel auxiliary layer 153 may lead the pixel electrodes AE1, AE2 and AE3 of the display device 10 to be formed in the emission areas EA1, EA2, and EA3, respectively, such that they are spaced from one another.

Although the first emission area EA1 and the third emission area EA3 have been described with reference to FIG. 6 for convenience of illustration, the second pixel auxiliary layer 153-2 overlapping with the second emission area EA2 may include the same structure and features as the first pixel auxiliary layer 153-1 and the third pixel auxiliary layer 153-3.

The light-emitting elements ED1, ED2 and ED3 may be located on the pixel auxiliary layer 153 and the second connection electrode CNE2, overlapping with the emission areas EA1, EA2 and EA3 and the non-emission area NLA.

The light-emitting elements ED1, ED2 and ED3 may include a first light-emitting element ED1, a second light-emitting element ED2 and a third light-emitting element ED3 in line with the emission areas EA1, EA2, and EA3, respectively. For example, the first light-emitting element ED1 may be disposed in the first emission area EA1, the second light-emitting element ED2 may be disposed in the second emission area EA2, and the third light-emitting element ED3 may be disposed in the third emission area EA3.

The light-emitting elements ED1, ED2 and ED3 may include pixel electrodes AE1, AE2 and AE3 in line with the emission areas EA1, EA2 and EA3, respectively, and may include a common emission material layer EL and a common electrode CE. Although the first light-emitting element ED1 and the third light-emitting element ED3 are shown in the drawings and described for convenience of illustration, the second light-emitting element ED2 may include the same structure and features.

The pixel electrodes AE1, AE2 and AE3 may be disposed on the second connection electrode CNE2 and the pixel auxiliary layer 153 in the emission areas EA1, EA2 and EA3 and the non-emission area NLA. As the pixel electrodes AE1, AE2 and AE3 are in contact with the second connection electrodes CNE2 exposed by the pixel auxiliary layer 153 and the second via layer 123, they may be electrically connected to the drain electrodes DE of the thin-film transistors TFT through the first connection electrodes CNE1 and the second connection electrodes CNE2.

The pixel electrodes AE1, AE2 and AE3 may include a first pixel electrode AE1, a second pixel electrode AE2 and a third pixel electrode AE3 in line with the emission areas EA1, EA2 and EA3, respectively. For example, the first pixel electrode AE1 may be disposed in the first emission area EA1, the second pixel electrode AE2 may be disposed in the second emission area EA2, and the third pixel electrode AE3 may be disposed in the third emission area EA3.

The pixel electrodes AE1, AE2 and AE3 may be a metal having high electrical conductivity. For example, the pixel electrodes AE1, AE2 and AE3 may have a stack structure of a material layer having a high work function such as indium-tin-oxide (ITO), indium-zinc-oxide (IZO), zinc oxide (ZnO) and indium oxide (In₂O₃), and a reflective material layer such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca) or a mixture thereof. A layer having a higher work function may be disposed on a higher layer than a reflective material layer so that it may be closer to the emission material layer EL. For example, the pixel electrodes AE1, AE2 and AE3 may have, but is not limited to, a multilayer structure of ITO/Mg, ITO/MgF, ITO/Ag, and ITO/Ag/ITO.

According to some embodiments, the pixel electrodes AE1, AE2 and AE3 in the respective emission areas EA1, EA2 and EA3 may be spaced from one another in the non-emission area NLA. As described above, the pixel electrodes AE1, AE2 and AE3 of the display device 10 may be disposed in the respective emission areas EA1, EA2 and EA3 such that they are spaced from each other by the protruding tips included in the pixel auxiliary layer 153. Accordingly, the pixel electrodes AE1, AE2 and AE3 of the display device 10 may be spaced from each other in the respective emission areas EA1, EA2 and EA3 without a mask during the fabrication process. In some embodiments, the second pixel electrode AE2 may have the same structure and features as the first pixel electrode AE1 and the third pixel electrode AE3.

According to some embodiments, a pixel electrode pattern AEP may be disposed in the recess R123 of the second via layer 123 in line with the non-emission area NLA. As the pixel auxiliary layer 153 includes protruding tips TIP, the pixel electrodes AE1, AE2 and AE3 are disconnected in the non-emission area NLA, and accordingly form the pixel electrode pattern AEP is formed as residues of the pixel electrodes AE1, AE2 and AE3. Accordingly, the pixel electrode pattern AEP may be spaced from the pixel electrodes AE1, AE2 and AE3 in the non-emission area NLA.

The separator 155 may be located on the pixel electrodes AE1, AE2 and AE3 in the non-emission area NLA. The separator 155 may have an overhang structure in which the upper surface is larger than the lower surface. Accordingly, the side surfaces of the separator 155 may have a reverse taper shape. It should be understood, however, that the present disclosure is not limited thereto. The side surfaces of the separator 155 may be formed perpendicular (e.g., substantially perpendicular or normal) to the pixel electrodes AE1, AE2 and AE3.

The separator 155 may define the emission areas EA1, EA2 and EA3 and the non-emission area NLA of the display device 10, and may assist deposition of a charge generation layer CGL included in the emission material layer EL so that it is separately deposited. This will be described in more detail later.

The separator 155 may include an organic material. As an example, the separator 155 may include an organic material such as an acrylic resin, an epoxy resin, a phenol resin, a polyamide resin and a polyimide resin. It should be understood, however, that the present disclosure is not limited thereto. The separators 155 may include any organic material as long as it is usable in photo lithography.

The emission material layer EL may be disposed on the separator 155 and the pixel electrodes AE1, AE2 and AE3. The emission material layer EL according to this embodiment may be disposed across the emission areas EA1, EA2 and EA3 and the non-emission area NLA. It should be noted that some elements included in the emission material layer EL may be separated by the separator 155, which will be described in more detail later.

The common electrode CE may be disposed on the emission material layer EL. The common electrode CE according to this embodiment may be a common layer disposed across the emission areas EA1, EA2 and EA3 and the non-emission area NLA. The common electrode CE may include a transparent conductive material so that light generated in the emission material layer EL can exit. The common electrode CE may receive a common voltage or a low-level voltage. When the pixel electrodes AE1, AE2 and AE3 receives the voltage equal to the data voltage and the common electrode CE receives the low-level voltage, a potential difference is formed between the pixel electrodes AE1, AE2 and AE3 and the common electrode CE, so that the emission material layer EL can emit light.

The common electrode CE may be formed of a transparent conductive material (TCP) such as ITO and IZO that can transmit light, or a semi-transmissive conductive material such as magnesium (Mg), silver (Ag) and an alloy of magnesium (Mg) and silver (Ag). When the common electrode CE is formed of a semi-transmissive metal material, the light extraction efficiency can be increased by utilizing microcavities.

A capping layer 159 may be disposed on the common electrode CE. The capping layer 159 may be a common layer disposed across the emission areas EA1, EA2 and EA3 and the non-emission area NLA. The capping layer 159 can prevent or reduce the light-emitting elements ED1, ED2 and ED3 from being damaged by outside air, and can prevent or reduce the delamination of the light-emitting elements ED1, ED2 and ED3 and the common electrode CE.

The capping layer 159 may include an inorganic material. As an example, the capping layer 159 may include aluminum oxide, titanium oxide, tantalum oxide, hafnium oxide, zinc oxide, silicon oxide, silicon nitride, and silicon oxynitride.

The thin-film encapsulation layer 170 may be disposed on the display element layer 150. The thin-film encapsulation layer 170 may include at least one inorganic film to prevent or reduce permeation of oxygen or moisture into the display element layer 150. In some embodiments, the thin-film encapsulation layer 170 may include at least one organic film to protect the display element layer 150 from particles such as dust. The thin-film encapsulation layer 170 may include a first encapsulation layer 171, a second encapsulation layer 173, and a third encapsulation layer 175. The first encapsulation layer 171 may be disposed on the common electrode CE, the second encapsulation layer 173 may be disposed on the first encapsulation layer 171, and the third encapsulation layer 175 may be disposed on the second encapsulation layer 173.

The first encapsulation layer 171 and the third encapsulation layer 175 may be inorganic films. For example, each of the first encapsulation layer 171 and the third encapsulation layer 175 may be made up of multiple films in which one or more inorganic films of a silicon nitride layer, a silicon oxynitride layer, a silicon oxide layer, a titanium oxide layer and an aluminum oxide layer are alternately stacked on one another.

The second encapsulation layer 173 may be an organic film. As an example, the second encapsulation layer 173 may include an organic material such as an acrylic resin, an epoxy resin, a phenol resin, a polyamide resin and a polyimide resin.

A color filter protection layer 185 may be located on the thin-film encapsulation layer 170. The color filter protection layer 185 may be disposed or provided entirely across the emission areas EA1, EA2 and EA3 and the non-emission area NLA. The color filter protection layer 185 can protect the color filter layer 190. The color filter protection layer 185 may be a single layer containing an inorganic material or an organic material, or may include multiple layers containing an inorganic material and an organic material.

For example, the inorganic material contained in the color filter protection layer 185 may include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, etc. The organic material contained in the color filter protection layer 185 may include an acrylic resin, an epoxy resin, a phenolic resin, a polyamide resin, a polyimide resin, etc.

The color filter layer 190 may include a plurality of first to third color filters 191, 193 and 195 associated with the emission areas EA1, EA2 and EA3, respectively. For example, the color filter layer 190 may include a first color filter 191 in the first emission area EA1, a second color filter 193 in the second emission area EA2, and a third color filter 195 in the third emission area EA3.

As described above, the emission material layer EL herein may be disposed in the emission areas EA1, EA2 and EA3 and be configured to emit lights of the same color. The lights of the same color output from the emission areas EA1, EA2 and EA3 may be converted into lights of different colors by the color filter layer 190 overlapping with the emission areas EA1, EA2 and EA3 to exit to the outside of the display device 10.

According to some embodiments, the first color filter 191 may selectively transmit light of the first color. For example, the first color filter 191 may be configured to transmit light of the first color (e.g., red light) and block or reduce or may be configured to absorb light of another color (e.g., green light and blue light). According to an embodiment of the present disclosure, the first color filter 191 may be a red color filter and may include a red colorant. Light (e.g., white light) emitted from each first light-emitting element ED1 may pass through the first color filter 191 and exit to the outside. Accordingly, light of the first color (e.g., red light) may exit from the first emission area EA1.

The second color filter 193 may selectively transmit light of the second color. For example, the second color filter 193 may be configured to transmit light of the second color (e.g., green light), and may block or reduce or be configured to absorb the light of the first color (e.g., red light), and the light of the third color (e.g., blue light). According to an embodiment, the second color filter 193 may be a green color filter and may include a green colorant. Light (e.g., white light) emitted from each second light-emitting element ED2 may pass through the second color filter 193 and exit to the outside. Accordingly, light of the second color (e.g., green light) may exit from the second emission area EA2.

The third color filter 195 may selectively transmit light of the third color. For example, the third color filter 195 may selectively transmit light of the third color (e.g., blue light) and may block or reduce and absorb light of the first color (e.g., red light) and light of the second color (e.g., green light).

According to an embodiment, the third color filter 195 may be a blue color filter and may include a blue colorant such as blue dye and blue pigment. Light (e.g., white light) emitted from each third light-emitting element ED3 may pass through the third color filter 195 and exit to the outside. Accordingly, light of the third color (e.g., blue light) may exit from the third emission area EA3.

According to an embodiment, the first to third color filters 191, 193 and 195 may include color filter patterns 190p that overlap each other in the non-emission area NLA. The color filter patterns 190p may be around (e.g., may surround) the emission areas EA1, EA2 and EA3, thereby preventing or reducing color mixing between the emission areas EA1, EA2 and EA3. The color filter patterns 190p can also work as light-blocking patterns and block or reduce the transmission of light. The color filter patterns 191p, 193p and 195p may be formed in one or more suitable configurations by neighboring color filter layers 190. For example, when the first color filter 191 and the third color filter 195 are adjacent to each other as shown in FIG. 6, the color filter pattern 190p may include a stack structure of the first color filter pattern 191p and the third color filter pattern 195p. Accordingly, the color filter pattern 190p may be formed in one or more suitable configurations.

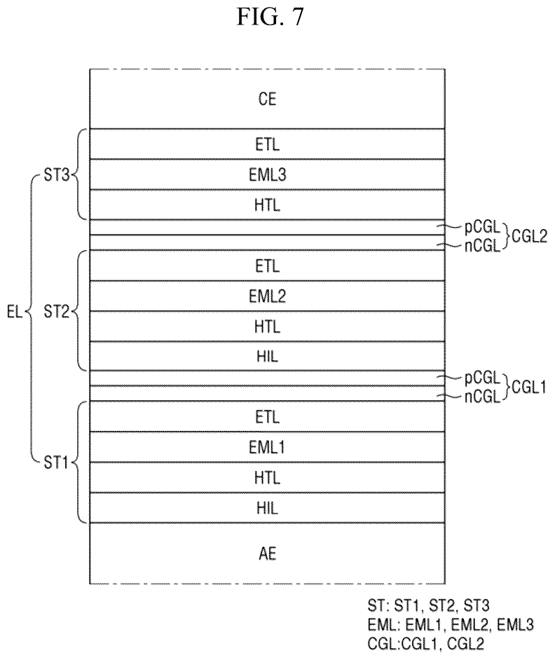

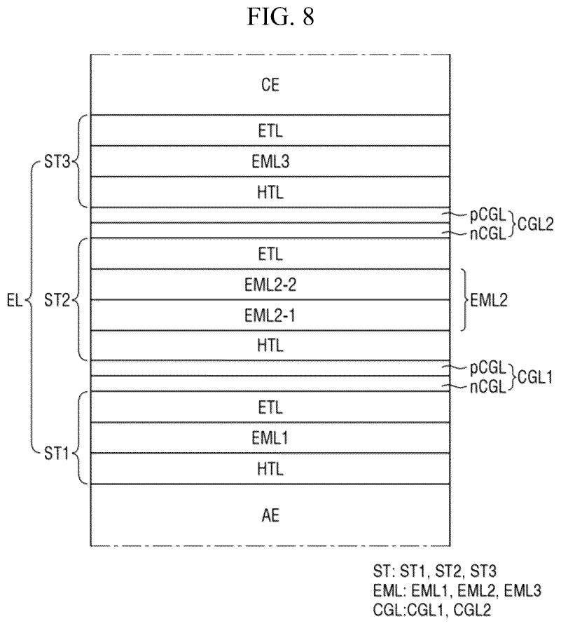

FIGS. 7 and 8 are cross-sectional views showing the emission material layer EL of FIG. 6.

Referring to FIGS. 7 and 8, the light-emitting elements ED1, ED2 and ED3 according to this embodiment may include pixel electrodes AE1, AE2 and AE3 and a common electrode CE facing each other in the third direction (z-axis direction), and emission stacks ST provided between the pixel electrodes AE1, AE2 and AE3 and the common electrode CE. The emission stacks ST may include a high-molecular or low-molecular organic material that is configured to emit light of a set or predetermined color. In addition to a variety of organic materials, the emission stacks ST may further include metal-containing compounds such as organometallic compounds, inorganic materials such as quantum dots, etc. Although a three (3) tandem structure including three emission stacks ST is shown in the drawings, the present disclosure is not limited thereto.

The emission stack ST may include at least one emissive layer EML. For example, the first emission stack ST1 may include a first emissive layer EML1, the second emission stack ST2 may include a second emissive layer EML2 in line with the first emissive layer EML1, and the third emission stack ST3 may include a third emissive layer EML3 in line with the first emissive layer EML1 and the second emissive layer EML2. For example, the first emissive layer EML1 may be configured to emit one of light of the first color, light of the second color and light of the third color, the second emissive layer EML2 may be configured to emit one of light of the first color, light of the second color and light of the third color, and the third emissive layer EML3 may be configured to emit one of light of the first color, light of the second color and light of the third color. According to some embodiments, the first emissive layer EML1, the second emissive layer EML2 and the third emissive layer EML3 may be configured to emit lights of the same color, and the first emissive layer EML1, the second emissive layer EML2 and the third emissive layer EML3 may be configured to emit lights of different colors. For example, the light of the first color may be red light, the light of the second color may be green light, and the light of the third color may be blue light, but the present disclosure is not limited thereto.

Referring to FIG. 8, according to another embodiment, the first emissive layer EML1 may be configured to emit a plurality of lights among light of a first color, light of a second color, light of a third color and light of a fourth color, the second emissive layer EML2 may be configured to emit a plurality of lights among light of the first color, light of the second color, light of the third color and light of the fourth color, and the third emissive layer EML3 may be configured to emit a plurality of lights among light of the first color, light of the second color, light of the third color and light of the fourth color. For example, when the second emissive layer EML2 emits a plurality of lights, the second emissive layer EML2 may be made up of multiple layers like a first sub-emissive layer EML2-1 and a second sub-emissive layer EML2-2. For example, the light of the first color may be red light, the light of the second color may be green light, the light of the third color may be blue light, and the light of the fourth color may be yellow light, but the present disclosure is not limited thereto.

Each emissive layer EML according to this embodiment may include a host and a dopant. The emissive layer EML may be formed by utilizing a phosphorescent or fluorescent material as the dopant in a host material. The material of the host is not particularly limited herein as long as it is typically utilized and may include Alq3(tris(8-hydroxyquinolino)aluminum), CBP(4,4′-bis(N-carbazolyl)-1,1′-biphenyl), PVK(poly(n-vinylcabazole)), ADN(9,10-di(naphthalen-2-yl)anthracene), TCTA(4,4′,4″-Tris(carbazol-9-yl)-triphenylamine), TPBi(1,3,5-tris(N-phenylbenzimidazole-2-yl)benzene), TBADN(3-tert-butyl-9,10-di(naphth-2-yl)anthracene), DSA(distyrylarylene), CDBP(4,4′-bis(9-carbazolyl)-2,2″-dimethyl-biphenyl), MADN(2-Methyl-9,10-bis(naphthalen-2-yl) anthracene), etc. The colors of light emitted from the emissive layer may be determined by a combination of the host material and the dopant material.

According to an embodiment of the present disclosure, a blue emissive layer that is configured to emit blue light may include a fluorescent material including one selected from among the group consisting of: spiro-DPVBi, spiro-6P, DSB(distyryl-benzene), DSA(distyryl-arylene), PFO(polyfluorene) polymer and PPV(poly(p-phenylene vinylene) polymer. The dopant material contained in the blue emissive layer may be, for example, a metal complex such as (4,6-F2ppy)2Irpic, or an organometallic complex. In some embodiments, the blue emissive layer may include a phosphorescent material including an organometallic complex such as (4,6-F2ppy)2Irpic.

According to an embodiment of the present disclosure, a green emissive layer that is configured to emit green light may include a fluorescent material containing Alq3(tris(8-hydroxyquinolino)aluminum). The dopant material contained in the green emissive layer may be, for example, a metal complex such as Ir(ppy)3(fac-tris(2-phenylpyridine)iridium) or an organometallic complex.

According to an embodiment of the present disclosure, a red emissive layer that is configured to emit red light may include a fluorescent material including PBD:Eu(DBM)3(Phen)(tris(dibenzoylmethanato)phenanthoroline europium) or perylene. The dopant material contained in the red emissive layer may be, for example, Metal complexes such as PIQIr(acac)(bis(1-phenylisoquinoline)acetylacetonate iridium), PQIr(acac)(bis(1-phenylquinoline)acetylacetonate iridium), and PQIr(tris(1-phenylquinoline)iridium) and PtOEP(octaethylporphyrin platinum, or an organometallic complex.

The emission stack ST may further include at least one intermediate layer overlapping with at least one emissive layer EML. As an example, the intermediate layer may include a hole injection layer HIL, a hole transport layer HTL, and an electron transport layer ETL. As shown in FIGS. 7 and 8, according to some embodiments, the hole transport layer HTL may combine the roles of the hole transport layer and the hole injection layer.

The hole transport layer HTL may be located close to the pixel electrodes AE1, AE2 and AE3, may facilitate the transport of holes, and may include a hole transport material. The hole transport material may include, but is not limited to, carbazole derivatives such as N-phenylcarbazole and polyvinylcarbazole, fluorene derivatives, triphenylamine derivatives such as TPD(N,N′-bis(3-methylphenyl)-N,N′-diphenyl-[1,1-biphenyl]-4,4′-diamine) and TCTA(4,4′,4″-tris(N-carbazolyl)triphenylamine), NPB(N,N′-di(1-naphthyl)-N,N′-diphenylbenzidine), TAPC(4,4′-Cyclohexylidene bis[N,N-bis(4-methylphenyl)benzenamine]), etc. This may be equally applied to the hole transport layer HTL included in the second emission stack ST2 and the third emission stack ST3.

In some embodiments, the electron transport layer ETL may be located close to the common electrode CE, may facilitate the transport of electrons, and may include an electron transport material. According to some embodiments, an electron injection layer EIL may be disposed between the common electrode CE and the electron transport layer ETL. For example, the electron transport material may include, but is not limited to, electron transparent material such as Alq3(Tris(8-hydroxyquinolinato)aluminum), TPBi(1,3,5-Tri(1-phenyl-1H-benzo[d]imidazol-2-yl)phenyl), BCP(2,9-Dimethyl-4,7-diphenyl-1,10-phenanthroline), Bphen(4,7-Diphenyl-1,10-phenanthroline), TAZ(3-(4-Biphenylyl)-4-phenyl-5-tert-butylphenyl-1,2,4-triazole), NTAZ(4-(Naphthalen-1-yl)-3,5-diphenyl-4H-1,2,4-triazole), tBu-PBD(2-(4-Biphenylyl)-5-(4-tert-butylphenyl)-1,3,4-oxadiazole), BAlq(Bis(2-methyl-8-quinolinolato-N1,O8)-(1,1′-Biphenyl-4-olato)aluminum), Bebq2(berylliumbis(benzoquinolin-10-olate), ADN(9,10-di(naphthalen-2-yl)anthracene) and a mixture thereof.

The charge generation layers CGL may be located between the emission stacks ST.

The charge generation layers CGL may be functional layers that control charge balance between the stacks ST. Accordingly, the charge generation layers CGL may provide charges to each of the first to third emissive layers EML1, EML2 and EML3, thereby increasing the luminous efficiency of the light-emitting elements ED1, ED2 and ED3 and lowering the driving voltage.

The charge generation layers CGL may include negative charge generation layer nCGL and positive charge generation layer pCGL. As an example, a negative charge generation layer nCGL may be disposed on each of the stacks ST, and then a positive charge generation layer pCGL may be disposed on the negative charge generation layer nCGL. The charge generation layer CGL may include a first charge generation layer CGL1 located between the first emission stack ST1 and the second emission stack ST2, and a second charge generation layer CGL2 located between the second emission stack ST2 and the third emission stack ST3.

The negative charge generation layer nCGL included in the first charge generation layer CGL1 (e.g., may include a conductive material or is a conductor) may be disposed in contact with the first emission stack ST1 and may supply electrons to the first emissive layer EML1 (and, e.g., the first emission layer may not include a conductor material or is not a conductor). The negative charge generation layer nCGL may include a host and a dopant. The host may include an organic material. The dopant may include a metal material. According to an embodiment, the negative charge generation layer nCGL may include an aryl amine-based organic compound such as α-NPD, 2-TNATA, TDATA, MTDATA, sprio-TAD and sprio-NPB.

The positive charge generation layer pCGL included in the first charge generation layer CGL1 may be disposed in contact with the second emission stack ST2 and may supply holes to the second emissive layer EML2. The positive charge generation layer pCGL may include a host and a dopant. The host may include an organic material. The dopant may include a metal material. According to an embodiment, the positive charge generation layer pCGL may include a charge generating compound made of metal, metal oxide, carbide, fluoride, or a mixture thereof. For example, the metal may be cesium (Cs), molybdenum (Mo), vanadium (V), titanium (Ti), tungsten (W), barium (Ba), or lithium (Li). In some embodiments, for example, the oxide, carbide and fluoride of the metal may be Re₂O₇, MoO₃, V₂O₅, WO₃, TiO₂, Cs₂CO₃, BaF, LiF, or CsF.

In some embodiments, the negative charge generation layer nCGL included in the second charge generation layer CGL2 may be in contact with the second emission stack ST2 and supply electrons to the second emissive layer EML2, and the positive charge generation layer pCGL included in the second charge generation layer CGL2 may be in contact with the third emission stack ST3 and supply holes to the third emissive layer EML3. Other redundant descriptions will not be provided.

FIG. 9 is an enlarged cross-sectional view showing the periphery of the first light-emitting element ED1 in the first emission area EA1 of FIG. 6.

Referring to FIG. 9, the second via layer 123 in the first emission area EA1 may include a first portion 123A and a second portion 123B. The first portion 123A and the second portion 123B of the second via layer 123 may be formed as the second via layer 123 is partially penetrated by a pixel electrode contact hole ACNTH. As a result, the first portion 123A and the second portion 123B of the second via layer 123 may be spaced from each other while exposing the second connection electrode CNE2. The first portion 123A of the second via layer 123 may be located on the opposite side in the first direction (x-axis direction) in the first emission area EA1, while the second portion 123B of the second via layer 123 may be located on one side in the first direction (x-axis direction) in the first emission area EA1.

The first pixel auxiliary layer 153-1 in the first emission area EA1 may include a first portion 153-1A and a second portion 153-1B. The first portion 153-1A and the second portion 153-1B of the first pixel auxiliary layer 153-1 may be formed as a portion of the first pixel auxiliary layer 153-1 is penetrated by the pixel electrode contact hole ACNTH. Accordingly, the first portion 153-1A and the second portion 153-1B of the first pixel auxiliary layer 153-1 may be spaced from each other while exposing the second connection electrode CNE2. The first portion 153-1A of the first pixel auxiliary layer 153-1 may be located on the opposite side in the first direction (x-axis direction) in the first emission area EA1, while the second portion 153-1B of the first pixel auxiliary layer 153-1 may be located on one side in the first direction (x-axis direction) in the first emission area EA1. In some embodiments, the first portion 153-1A of the first pixel auxiliary layer 153-1 may be located on the first portion 123A of the second via layer 123, and the second portion 153-1B of the first pixel auxiliary layer 153-1 may be located on the second portion 123B of the second via layer 123.

The first pixel electrode AE1 in the first emission area EA1 may cover the first portion 153-1A and the second portion 153-1B of the first pixel auxiliary layer 153-1, and may cover the second connection electrode CNE2 exposed by the first pixel auxiliary layer 153-1 and the second via layer 123. The first pixel electrode AE1 may be extended on the first portion 153-1A of the first pixel auxiliary layer 153-1 and may be in contact with the exposed part of the second connection electrode CNE2, and may be extended from it to the exposed part of the second portion 153-1B of the first pixel auxiliary layer 153-1.

In the first emission area EA1, an emission material layer EL, a common electrode CE, a capping layer 159, a first encapsulation layer 171 and a second encapsulation layer 173 may be stacked on the first pixel electrode AE1 in this order in of the third direction (z-axis direction). Other redundant descriptions will not be provided.

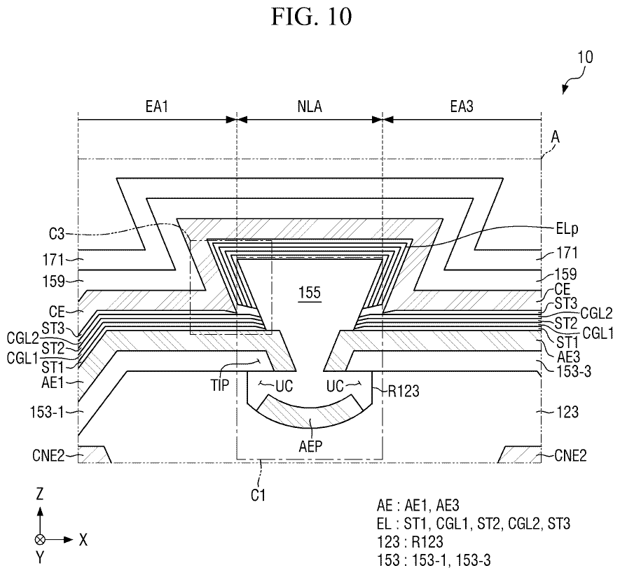

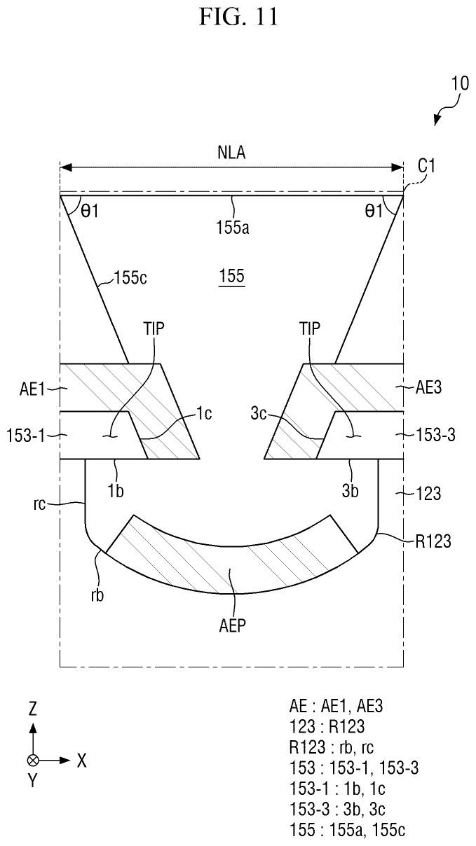

FIG. 10 is an enlarged cross-sectional view of area A of FIG. 6. FIG. 11 is an enlarged cross-sectional view of area C1 of FIG. 10.

Referring to FIGS. 10 and 11, as described above, the second via layer 123 of the display device 10 may include a recess R123 in the non-emission area NLA, the pixel auxiliary layer 153 of the display device 10 may include a first pixel auxiliary layer 153-1 in line with the first emission area EA1 and a third pixel auxiliary layer 153-3 in line with the third pixel auxiliary layer 153-3. The first pixel auxiliary layer 153-1 and the third pixel auxiliary layer 153-3 may be spaced from each other in the non-emission area NLA.

According to some embodiments, the recess R123 and the pixel auxiliary layer 153 included in the display device 10 may be formed via a dry etching process during the fabrication process. For example, the pixel auxiliary layer 153 may be deposited on the entire surface across the emission areas EA1, EA2 and EA3 and the non-emission area NLA, and then may be spaced from one another in the non-emission area NLA by a dry etching process during the fabrication process.

Accordingly, the pixel auxiliary layer 153 may include a first pixel auxiliary layer 153-1, a second pixel auxiliary layer 153-2 and a third pixel auxiliary layer 153-3 in line with the emission areas EA1, EA2 and EA3, respectively.

In some embodiments, the second via layer 123 may be etched concurrently (e.g., simultaneously) with the pixel auxiliary layer 153. Accordingly, the second via layer 123 may include the recess R123 that is recessed toward the first via layer 121. For example, the recess R123 may be isotropically etched via a dry etching process.

As shown in FIG. 11, the recess R123 of the second via layer 123 may include both (e.g., simultaneously) side surfaces rc and a bottom surface rb formed via a dry etching process.

According to this embodiment, the pixel auxiliary layer 153 may include a material with a lower dry etch rate than the second via layer 123, and thus the pixel auxiliary layer 153 may include protruding tips TIP from the side surfaces rc of the recess R123 in the first direction (x-axis direction) in the non-emissive area NLA. In other words, the side surfaces rc of the recess R123 may be depressed in the first direction (x-axis direction) than the protruding tips TIP of the pixel auxiliary layer 153. As a result, undercuts UC may be formed between the protruding tips TIP included in the pixel auxiliary layer 153 and the side surfaces rc of the recess R123. In some embodiments, the protruding tip is on one side of the first pixel auxiliary layer 153-1 and extends in a first direction (e.g., x-direction) from the side surface rc of the recess R123 in the non-emission area. More specifically, for example, the protruding tip of the first pixel auxiliary layer 153-1 may include a side surface 1c and a bottom surface 1b, and the protruding tip of the third pixel auxiliary layer 153-3 may include a side surface 3c and a bottom surface 3b. The bottom surface 1b of the first pixel auxiliary layer 153-1 and the bottom surface 3b of the third pixel auxiliary layer 153-3 may face the recess R123, and the side surface 1c of the first pixel auxiliary layer 153-1 and the side surface 3c of the third pixel auxiliary layer 153-3 may face each other in the non-emission area NLA.

According to this embodiment, during the process of fabricating the display device, a subsequent process may be performed with the empty recess R123 of the second via layer 123. The pixel electrodes AE1, AE2 and AE3 may be formed in display device 10 after a dry etching process.

As described above, because the pixel auxiliary layer 153 includes the protruding tips TIP in the display device 10, the pixel electrodes AE1, AE2 and AE3 may include the first pixel electrode AE1 in line with the first emission area EA1 and the third pixel electrode AE3 in line with the third emission area EA3. The first pixel electrode AE1 and the third pixel electrode AE3 may be spaced from each other by the respective protruding tips TIP of the pixel auxiliary layer 153.

For example, in the deposition process of the pixel electrodes AE1, AE2 and AE3 included in the display device 10, the material for forming the pixel electrodes AE1, AE2 and AE3 may be deposited not in the third direction (z-axis direction) perpendicular (e.g., substantially perpendicular or normal) to the substrate 110 but in an inclined direction with respect to the substrate 110, i.e., a direction between the first direction (x-axis direction) and the third direction (z-axis direction). By doing so, the pixel electrodes AE1, AE2 and AE3 may be deposited on the side surface 1c and 3c included in the protruding tips TIP of the pixel auxiliary layer 153, and may be partially deposited inside the recess R123 included in the second via layer 123. It should be noted that the pixel electrodes AE1, AE2 and AE3 may not be in contact with the lower surfaces 1b and 3b included in the protruding tips TIP of the pixel auxiliary layer 153.

Parts of the pixel electrodes AE1, AE2 and AE3 deposited inside the recess R123 of the second via layer 123 may form a pixel electrode pattern AEP spaced from the pixel electrodes AE1, AE2 and AE3. The pixel electrode pattern AEP may be located inside the recess R123 in the non-emission area NLA. For example, the pixel electrode pattern AEP may be in contact with the bottom surface rb of the recess R123.

Although only the first emission area EA1, the non-emission area NLA and the third emission area EA3 have been described with reference to the drawings for convenience of illustration, the second pixel auxiliary layer 153-2 in the second emission area EA2 may have the same structure and features as the first pixel auxiliary layer 153—in the first emission area EA1 and the third pixel auxiliary layer 153-3 in the third emission area EA3, and the second pixel electrode AE2 in the second emission area EA2 may have the same structure and features as the first pixel electrode AE1 and the third pixel electrode AE3.

A separator 155 may be located on the pixel electrodes AE1, AE2 and AE3 in the non-emission area NLA.

As shown in FIG. 11, the separator 155 included in the display device 10 may include a top surface 155a and side surfaces 155c. The inclination angle θ1 formed by the top surface 155a and the side surfaces 155c of the separator 155 may be, but is not limited to, an acute angle. According to some embodiments, the inclination angle θ1 formed by the top surface 155a and the side surfaces 155c of the separator 155 may include a right angle. The inclination angle θ1 of the separator 155 according to this embodiment may be adjusted by adjusting the exposure amount of the photolithography of the display device 10.

According to some embodiments, the separator 155 may define the emission areas EA1, EA2 and EA3 and the non-emission area NLA of the display device 10, and may also assist so that the charge generation layer CGL included in the emission material layer EL is disconnected.

Typically, when the pixel electrodes AE1, AE2 and AE3 and the charge generation layer CGL, which have conductive characteristics, are connected instead of being disconnected, leakage current defects may occur in the display device. For this reason, it may be important for display devices that the pixel electrodes AE1, AE2 and AE3 and the charge generation layers CGL, which have conductive characteristics (e.g., be a conductor), are disconnected or separated.

In the display device 10 according to this embodiment, the charge generation layers CGL may be disconnected by the shape of the separator 155 in the emission areas EA1, EA2 and EA3. In some embodiments, as the pixel auxiliary layer 153 includes the protruding tips TIP in the display device 10 according to this embodiment, the pixel electrodes AE1, AE2 and AE3 may be disconnected in the emission areas EA1, EA2 and EA3, respectively. Accordingly, the leakage current defects can be solved in the display device 10 according to this embodiment.

In some embodiments, the display device 10 according to this embodiment can ensure the maximum emission areas EA1, EA2 and EA3 because the separator 155 is formed with the minimum area. In this manner, the display device 10 according to this embodiment can be implemented with a high-resolution.

According to some embodiments, the separator 155 may be in line with the recess R123 included in the second via layer 123. As described above, a subsequent process may be performed with the empty recess R123 of the second via layer 123. Accordingly, the recess R123 of the second via layer 123 may be filled with a material forming the separator 155 during the process of forming the separator 155. Accordingly, the inside of the recess R123 and the separator 155 may be filled with the same material and connected with each other.

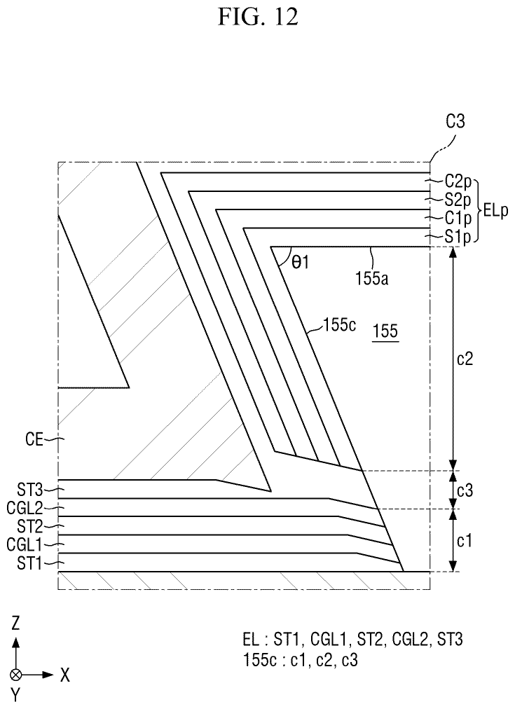

FIG. 12 is an enlarged, cross-sectional view of area C3 of FIG. 11.

Referring to FIGS. 10 and 12, the first emission stack ST1, the first charge generation layer CGL1, the second emission stack ST2 and the second charge generation layer CGL2 included in the emission material layer EL may be disconnected due to the separator 155 and thus may not cover the upper surface 155a of the separator 155. As a result, an emission pattern ELp may be formed on the side surface 155c and the top surface 155a of the separator 155. The emission pattern ELp may include a first stack pattern S1p, a first charge pattern C1p, a second stack pattern S2p, and a second charge pattern C2p.

For example, the first emission stack ST1 may be located on the first pixel electrode AE1 and may be in contact with the side surface 155c of the separator 155. The first emission stack ST1 may include a first stack pattern S1p that is not connected but is separated due to the separator 155. The first stack pattern S1p may include the same material as the first emission stack ST1. The first stack pattern Sp may be spaced from the first emission stack ST1 and in contact with the side surfaces 155c and the top surface 155a of the separator 155. The first stack pattern S1p may be formed as a result of the first emission stack ST1 that is not formed on the entire surface but is separated from one another due to the shape of the separator 155.

The first charge generation layer CGL1 may be located on the first emission stack ST1 and may be in contact with the side surfaces 155c of the separator 155. The first charge generation layer CGL1 may include a first charge pattern C1p that is not connected but is spaced from each other by the separator 155. The first charge pattern C1p may include the same material as the first charge generation layer CGL1. The first charge pattern C1p may be located on the side surfaces 155c and the top surface 155a of the separator 155 and spaced from the first charge generation layer CGL1, and the first charge pattern C1p may be located in contact with the first stack pattern S1p. The first charge pattern C1p may be formed as a result of the first charge generation layer CGL1 that is not formed on the entire surface but is separated from one another due to the shape of the separator 155.

The second emission stack ST2 may be located on the first charge generation layer CGL1 and may be in contact with the side surface 155c of the separator 155. The second emission stack ST2 may include a second stack pattern S2p that is not connected but is separated due to the separator 155. The second stack pattern S2p may include the same material as the second emission stack ST2. The second stack pattern S2p may be spaced from the second emission stack ST2, and may be located on the side surface 155c and the top surface 155a of the separator 155, and the second stack pattern S2p may be located in contact with the first charge pattern C1p. The second stack pattern S2p may be formed as a result of the second emission stack ST2 that is not formed on the entire surface but is separated from one another due to the shape of the separator 155.

The second charge generation layer CGL2 may be located on the second emission stack ST2 and may be in contact with the side surfaces 155c of the separator 155. The second charge generation layer CGL2 may include a second charge pattern C2p that is not connected but is spaced from each other by the separator 155. The second charge pattern C2p may include the same material as the second charge generation layer CGL2. The second charge pattern C2p may be spaced from the second charge generation layer CGL2 and may be located on the side surface 155c and the top surface 155a of the separator 155, and the second charge pattern C2p may be located in contact with the second stack pattern S2p. The second charge pattern C2p may be formed as a result of the second charge generation layer CGL2 that is not formed on the entire surface but is separated from one another due to the shape of the separator 155.

The third emission stack ST3 included in the emission material layer EL may be located on the second charge generation layer CGL2 and the second charge pattern C2p, and the third emission stack ST3 may be located to completely cover the second charge generation layer CGL2 and the second charge pattern C2p. In other words, the third emission stack ST3 may not be disconnected by the separator 155 but may be located on the entire surface across the emission areas EA1, EA2 and EA3 and the non-emission area NLA.

As shown in FIG. 12, the side surface 155c of the separator 155 may include: a first portion c1 in contact with the first emission stack ST1, the first charge generation layer CGL1, the second emission stack ST2 and the second charge general layer CGL2 of the emission material layer EL; a second portion c2 in contact with the first stack pattern Sip of the emission pattern ELp; and a third portion c3 in contact with the third emission stack ST3. The first portion c1 and the second portion c2 included in the side surface 155c of the separator 155 may be spaced from each other by the third portion c3.

Although the emission material layer EL includes the first emission stack ST1, the first charge generation layer CGL1, the second emission stack ST2, the second charge generation layer CGL2 and the third emission stack ST3 in the drawings for convenience of illustration, the present disclosure is not limited thereto. The emission material layer EL of the display device 10 may include any structure including at least two emission stacks ST and at least one charge generation layer CGL located between the emission stacks ST, and in such a structure, the charge generation layers CGL are separated by the separator 155. The last emission stack ST located toward the common electrode CE may not be disconnected by the separator 155 but may cover the entire surface of the emission areas EA1, EA2 and EA3 and the non-emission area NLA.

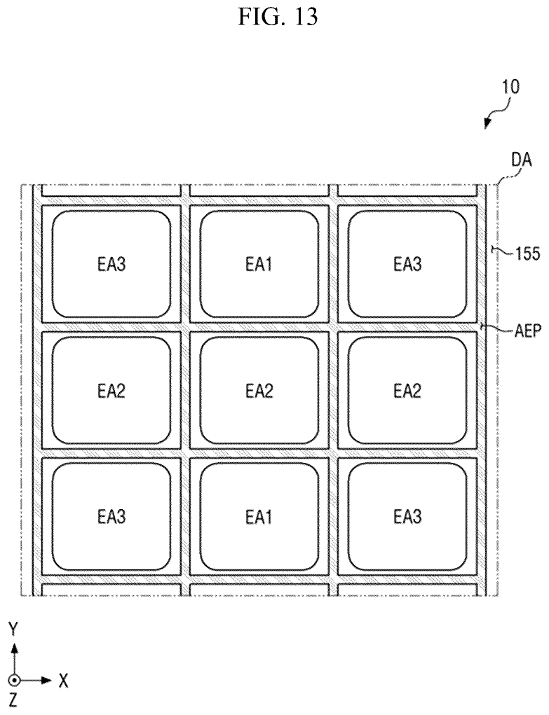

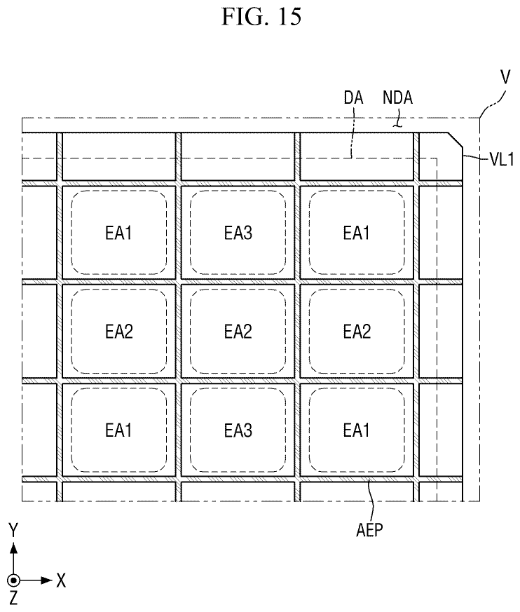

FIG. 13 is a plan view showing the separator 155 and the pixel electrode pattern AEP in the display area DA. FIG. 15 is an enlarged plan view of area V of FIG. 4.

Referring to FIG. 13, the separator 155 may have a mesh pattern in a plan view. The separator 155 may define the emission areas EA1, EA2 and EA3 and the non-emission area NLA in a plan view, and the separator 155 may surround the emission areas EA1, EA2 and EA3 in a plan view. This may refer to that the separator 155 surrounds the light-emitting elements ED1, ED2 and ED3 that overlap the emission areas EA1, EA2 and EA3, respectively. That is to say, the separator 155 may directly transmit the lights emitted from the emission areas EA1, EA2 and EA3 in a plan view.

In some embodiments, a plurality of structures disposed in the emission areas EA1, EA2 and EA3 may be located inside the separator 155 in a plan view. For example, a pixel electrode contact hole ACNTH in line with the emission areas EA1, EA2 and EA3 may be located inside the separator 155 in a plan view. In other words, the pixel electrode contact hole ACNTH in line with the emission areas EA1, EA2 and EA3 may be completely surrounded by the separator 155 in a plan view.

In some embodiments, the pixel electrode pattern AEP may be formed in a mesh pattern in the non-emission area NLA in a plan view. In other words, the pixel electrode pattern AEP may overlap with the separator 155 in a plan view.

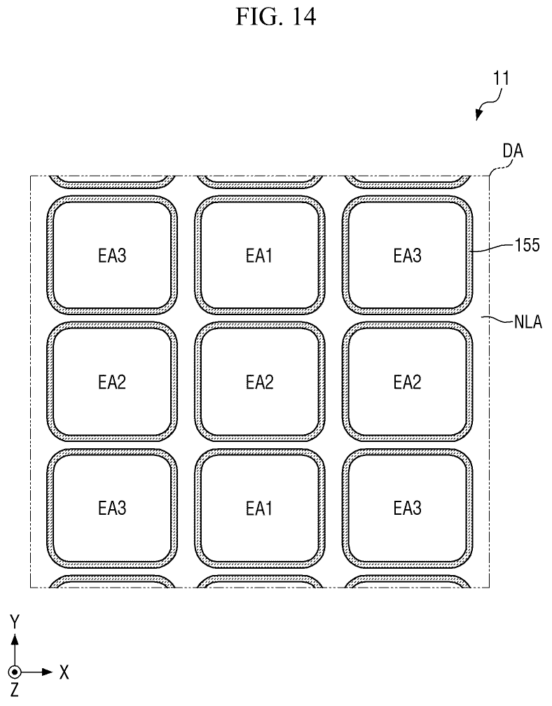

FIG. 14 is a plan view showing a layout of separators 155 in a display area DA according to another embodiment.

Referring to FIG. 14, the separators 155 in a display device 11 are disposed in the non-emission area NLA and surround the emission areas EA1, EA2 and EA3 in a plan view like the display device 10, but the separators individually surround the respective emission areas EA1, EA2 and EA3 in a plan view unlike the display device 10. As an example, a separator 155 around (e.g., surrounding) a first emission area EA1 may be spaced from a separator 155 around (e.g., surrounding) a third emission area EA3 and a separator 155 around (e.g., surrounding) a second emission area EA2. In other words, the separators 155 included in the display device 11 may surround the light-emitting elements ED1, ED2 and ED3 in the emission area EA1, EA2 and EA3, respectively. The separators 155 around (e.g., surrounding) the respective light-emitting element ED1, ED2 and ED3 may be spaced from one another. In some embodiments, the display device 11 may have a plurality of separators 155 spaced from each other in the non-emission area NLA in a cross-sectional view. For example, in the display device 11 according to the embodiment, two separators 155 may be located adjacent to the respective emission areas EA1, EA2 and EA3 in the non-emission area NLA.

The emission areas EA1, EA2 and EA3 of the display device 11 according to the embodiment may be defined by the separators 155 adjacent to the neighboring emission areas EA1, EA2 and EA3. Referring to FIG. 15, the pixel electrode pattern AEP formed in a mesh pattern in the display area DA in a plan view may be connected to the first voltage line VL1 located in the non-display area NDA described above in FIG. 4. Accordingly, the pixel electrode pattern AEP included in the display device 10 does not remain as a floating electrode and can be electrically stable.

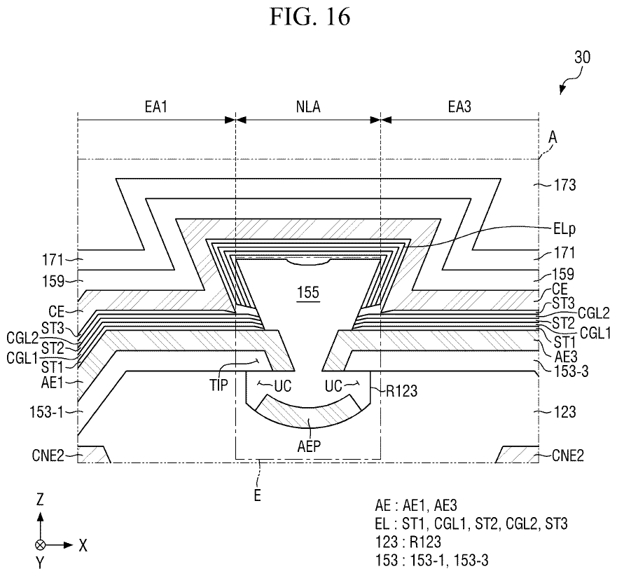

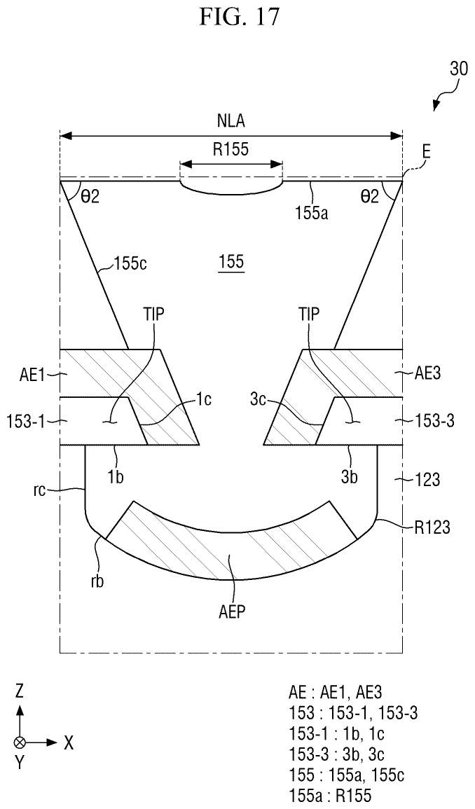

FIG. 16 is an enlarged cross-sectional view another example of area A of FIG. 6. FIG. 17 is an enlarged cross-sectional view of area E of FIG. 16 according to another embodiment.

Referring to FIGS. 16 and 17, a second via layer 123 of a display device 30 may include a recess R123 in the second via layer 123 in the non-emission area NLA, and a recess R123 of the display device 30 may include both (e.g., simultaneously) side surfaces rc and a bottom surface rb. The side surfaces rc of the recess R123 may be more depressed in the first direction (x-axis direction) than the protruding tips TIP of the pixel auxiliary layer 153. In some embodiments, the bottom surface rb of the recess R123 may be in contact with the pixel electrode pattern AEP.

The pixel auxiliary layer 153 of the display device 30 may include first to third pixel auxiliary layers 153-1, 153-2 and 153-3 disposed in the emission areas EA1, EA2, and EA3, respectively. The pixel auxiliary layer 153 of the display device 30 may include protruding tips TIP that protrude from the side surfaces rc of the recess R123 in the non-emission area NLA. Undercuts UC may be formed between the protruding tips TIP of the pixel auxiliary layer 153 and the side surfaces rc of the recess R123. The protruding tip TIP of the first pixel auxiliary layer 153-1 may include a bottom surface 1b and a side surface 1c facing the recess R123, and the protruding tip TIP of the third pixel auxiliary layer 153-3 may include a bottom surface 3b and a side surface 3c facing the recess R123.

The pixel electrodes AE1, AE2 and AE3 of the display device 30 may include first to third pixel electrodes AE1, AE2 and AE3 disposed in the emission areas EA1, EA2 and EA3, respectively. The first to third pixel electrodes AE1, AE2 and AE3 may cover the side surfaces of the first to third pixel auxiliary layers 153-1, 153-2 and 153-3, respectively. Although only the first emission area EA1, the non-emission area NLA and the third emission area EA3 have been described with reference to the drawings for convenience of illustration, the second pixel auxiliary layer 153-2 in the second emission area EA2 may have the same structure and features as the first pixel auxiliary layer 153—in the first emission area EA1 and the third pixel auxiliary layer 153-3 in the third emission area EA3, and the second pixel electrode AE2 in the second emission area EA2 may have the same structure and features as the first pixel electrode AE1 and the third pixel electrode AE3.

The separator 155 included in the display device 30 may include a top surface 155a and side surfaces 155c. An inclination angle θ2 formed by the top surface 155a and the side surfaces 155c of the separator 155 included in the display device 30 may be, but is not limited to, an acute angle. According to some embodiments, the inclination angle θ2 formed by the top surface 155a and the side surfaces 155c of the separator 155 may include a right angle. The inclination angle θ2 of the separator 155 according to this embodiment may be adjusted by adjusting the exposure amount of the photolithography of the display device 30. Other redundant descriptions will not be provided.

The display device 30 according to this embodiment is different from the display device 10 according to other embodiments in that it includes a recess R155 in the upper surface 155a of the separator 155.

According to some embodiments, the recess R123 and the pixel auxiliary layer 153 included in the display device 30 may be formed via a dry etching process during the fabrication process. By this process, the pixel auxiliary layer 153 may be spaced from one another in the non-emission area NLA, and the pixel auxiliary layer 153 may include protruding tips TIP in the non-emission area NLA. Additionally, in substantially the same process, the recess R123 of the second via layer 123 may be etched. In this process, a subsequent process may be performed with the empty recess R123 of the second via layer 123. The pixel electrodes AE1, AE2 and AE3 may be formed in display device 30 after a dry etching process. As the pixel auxiliary layer 153 includes the protruding tips TIP, the pixel electrodes AE1, AE2 and AE3 of the display device 30 may include the pixel electrode pattern AEP inside the recess R123. The pixel electrode pattern AEP of the display device 30 may be in contact with the bottom surface rb of the recess R123. The other elements are identical to those described above; and, therefore, the redundant description will not be provided.

Subsequently, the display device 30 may form a separator 155 on the pixel electrodes AE1, AE2 and AE3. The separator 155 may be formed via a photolithography process during the fabrication process. According to this embodiment, during the process of forming the separator 155 in the display device 30, the recess R123 may be filled with the same material as the separator 155. In some embodiments, after the separator 155 is formed, the recess R123 of the second via layer 123 may be filled with the material forming the separator 155 via a subsequent vacuum process. That is to say, the material forming the separator 155 of the display device 30 may be identical to the material inside the recess R123.

The recess R155 formed in a portion of the upper surface 155a of the separator 155 in the display device 30 may be formed via the above-described vacuum process. In other words, because the recess R155 is formed in a portion of the upper surface 155a of the separator 155, it can be seen that a vacuum process is included in the process of fabricating the display device 30.

According to some embodiments, the separator 155 may define the emission areas EA1, EA2 and EA3 of the display device 10, and may also assist so that the charge generation layer CGL included in the emission material layer EL is disconnected, which may each independently be the same structure and features as the display device 10 described above. In some embodiments, the emission material layer EL of the display device 30 may be covered by the common electrode CE, the first encapsulation layer 171, and the second encapsulation layer 173. Other redundant descriptions will not be provided.

In the present disclosure, singular expressions may include plural expressions unless the context clearly indicates otherwise. It will be further understood that the terms “comprise(s),” “include(s),” or “have/has” when utilized in the present disclosure, specify the presence of stated features, integers, steps, operations, elements, and/or components, but do not preclude the presence or addition of one or more other features, integers, steps, operations, elements, components, and/or groups thereof. The “/” utilized herein may be interpreted as “and” or as “or” depending on the situation.

Throughout the present disclosure, when a component such as a layer, a film, a region, or a plate is mentioned to be placed “on” another component, it will be understood that it may be directly on another component or that another component may be interposed therebetween. In some embodiments, “directly on” may refer to that there are no additional layers, films, regions, plates, etc., between a layer, a film, a region, a plate, etc. and the other part. For example, “directly on” may refer to two layers or two members are disposed without utilizing an additional member such as an adhesive member therebetween.

In the present disclosure, although the terms “first,” “second,” etc., may be utilized herein to describe one or more elements, components, regions, and/or layers, these elements, components, regions, and/or layers should not be limited by these terms. These terms are only utilized to distinguish one component from another component.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

In present disclosure, “not include a or any ‘component’” “exclude a or any ‘component’”, “‘component’-free”, and/or the like refers to that the “component” not being added, selected, or utilized as a component in a compound/composition, but the “component” of less than a suitable amount may still be included due to other impurities and/or external factors in a composition.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

As utilized herein, the term “and/or” includes any and all combinations of one or more of the associated listed items. Throughout the disclosure, the expression “at least one of a, b or c”, “at least one of a-c”, “at least one of a to c”, “at least one of a, b, and/or c”, “at least one among a to c”, etc., indicates only a, only b, only c, both (e.g., simultaneously) a and b, both (e.g., simultaneously) a and c, both (e.g., simultaneously) b and c, all of a, b, and c, or variations thereof.

In the present specification, “including A or B”, “A and/or B”, etc., represents A or B, or A and B.

The light-emitting device, the display device, the electronic apparatus, the electronic equipment, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Features of one or more suitable embodiments of the disclosure may be combined partially or totally. As will be clearly appreciated by those skilled in the art, technically one or more suitable interactions and operations are possible. Also, one or more suitable embodiments can be practiced individually or in combination.

In concluding the detailed description, those skilled in the art will appreciate that many variations and modifications can be made to the described embodiments without substantially departing from the principles of the present disclosure. Therefore, the disclosed embodiments of the present disclosure are utilized in a generic and descriptive sense and not for purposes of limitation.

What is claimed is:

1. A display device comprising:
a substrate comprising an emission area and a non-emission area;
a via layer on the emission area and the non-emission area of the substrate and comprising a first recess toward the substrate in the non-emission area;
a first pixel auxiliary layer on the via layer and comprising a protruding tip on one side of the first pixel auxiliary layer and extending in a first direction from a side surface of the first recess in the non-emission area;
a first pixel electrode on the first pixel auxiliary layer;
a separator on the first pixel electrode in the non-emission area;
a charge generation layer on the first pixel electrode in the emission area;
a charge pattern on the separator, the charge pattern and the charge generation layer comprise a same material; and
a common electrode on the charge generation layer and the charge pattern,
wherein the charge generation layer is in contact with a side surface of the separator, and
wherein the charge generation layer and the charge pattern are spaced from each other, and the common electrode on the charge generation layer and the common electrode on the charge pattern are provided as one body.

2. The display device of claim 1, wherein the separator comprises a first surface opposite to the first pixel electrode, and
wherein an inclination angle formed by the side surface of the separator and the first surface is either an acute angle or a right angle.

3. The display device of claim 2, further comprising:
a first emissive layer between the charge generation layer and the common electrode,
wherein the first emissive layer covers the charge generation layer and the charge pattern, and
wherein the first emissive layer is in contact with the side surface of the separator.

4. The display device of claim 3, wherein the side of the separator comprises
a first portion in contact with the charge generation layer;
a second portion overlapping with the charge pattern in a direction parallel to the substrate; and
a third portion in contact with the first emissive layer, and
wherein the third portion is between the first portion and the second portion.

5. The display device of claim 4, wherein the charge generation layer comprises a conductive material, and wherein the first emissive layer does not comprise a conductive material.

6. The display device of claim 1, wherein an undercut is located between the protruding tip of the first pixel auxiliary layer and the side surface of the first recess.

7. The display device of claim 6, wherein the protruding tip of the first pixel auxiliary layer has a bottom surface facing the first recess, and a first side surface connected to the bottom surface,
wherein the first pixel electrode is in contact with the first side surface, and
wherein the first pixel electrode is not in contact with the bottom surface.

8. The display device of claim 7, further comprising:
a second pixel auxiliary layer in the non-emission area and spaced from the first pixel auxiliary layer with the separator therebetween; and
a second pixel electrode on the second pixel auxiliary layer,
wherein the first pixel electrode and the second pixel electrode are spaced from each other with the separator therebetween.

9. The display device of claim 1, further comprising:
a second emissive layer between the first pixel electrode and the charge generation layer; and
an emission pattern between the separator and the charge pattern and comprising a same material as the second emissive layer,
wherein the second emissive layer and the emission pattern are in contact with the side surface of the separator.

10. The display device of claim 9, wherein the second emissive layer and the emission pattern are spaced from each other.

11. The display device of claim 1, further comprising: a connection electrode between the substrate and the via layer in the emission area,
wherein the via layer exposes the first via layer and the connection electrode and comprises a second via layer spaced from the first via layer in a direction parallel to the substrate.

12. The display device of claim 11, wherein the first via layer and the second via layer are spaced from each other by a pixel electrode contact hole in the emission area, and
wherein the pixel electrode contact hole is inside the separator in a plan view.

13. The display device of claim 12, wherein the first pixel auxiliary layer further comprises:
a first subsidiary portion in contact with the first via layer; and
a second subsidiary portion spaced from the first subsidiary portion by the pixel electrode contact hole and in contact with the second via layer, and
wherein the first subsidiary portion and the second subsidiary portion are connected by the first pixel electrode.

14. The display device of claim 1, wherein the separator has a reverse taper shape.

15. The display device of claim 14, wherein the first recess is filled with a same material as the separator, and wherein the first recess and the separator are formed as one body.

16. The display device of claim 2, wherein the first surface of the separator comprises a second recess toward the substrate.

17. A display device comprising:
a substrate comprising a display area and a non-display area, the display area comprising an emission area and a non-emission area;
a via layer on the substrate and comprising a recess toward the substrate in the non-emission area;
a first pixel auxiliary layer on the via layer and comprising a protruding tip on one side of the first pixel auxiliary layer and extending in a first direction from a side surface of the recess in the non-emission area;
a first pixel electrode on the first pixel auxiliary layer;
a first pixel electrode pattern in the recess, the first pixel electrode pattern and the first pixel electrode comprise a same material and the first pixel electrode pattern is spaced from the first pixel electrode;
a separator on the first pixel electrode in the non-emission area; and
a power electrode in the non-display area and surrounding the display area,
wherein the separator does not overlap with the emission area, and
wherein the separator completely surrounds the emission area in a plan view.

18. The display device of claim 17, wherein the first pixel electrode pattern does not overlap with the emission area, and wherein the separator and the first pixel electrode pattern have a mesh pattern in the plan view.

19. The display device of claim 18, wherein the first pixel electrode pattern is connected to the power electrode in the non-display area in the plan view.

20. The display device of claim 19, wherein the separator and the first pixel electrode pattern overlap each other in the plan view.
